(19) United States
(12) Patent Application Publication
(10) Pub. No.: US 2024/0371935 A1
(43) Pub. Date: Nov. 7, 2024

(54) SEMICONDUCTOR DEVICE AND METHODS OF FABRICATION THEREOF

(71) Applicant: TAIWAN SEMICONDUCTOR MANUFACTURING COMPANY, LTD., Hsinchu (TW)

(72) Inventors: Han-Yu Tang, Hsinchu (TW); Chih-Chiang Chang, Hsinchu (TW); Ming-Hua Yu, Taipei City (TW); Chii-Horng Li, Tainan City (TW); Wei-Jung Lin, Hsinchu (TW)

(21) Appl. No.: 18/238,247

(22) Filed: Aug. 25, 2023

Related U.S. Application Data
(60) Provisional application No. 63/463,642, filed on May 3, 2023.

(51) Int. Cl. H01L 29/08; H01L 29/40; H01L 29/417; H01L 29/66; H01L 29/775; H01L 29/78; H01L 29/786

(52) U.S. Cl. CPC H01L 29/0847; H01L 29/401; H01L 29/41733; H01L 29/66439; H01L 29/6656; H01L 29/66742; H01L 29/775; H01L 29/7848; H01L 29/78696; H01L 29/42392

(57) ABSTRACT

A semiconductor device structure is provided. The semiconductor device structure includes a source/drain (S/D) feature disposed in a recess between two adjacent channel regions, wherein the S/D feature comprises an epitaxial layer conformally deposited on an exposed surface of the recess. The structure also includes a silicide layer conformally disposed on the S/D feature, and a S/D contact disposed on the silicide layer, wherein the S/D contact has a first portion extending into the recess, and the first portion has at least three surfaces being surrounded by the silicide layer and the S/D feature.

### CROSS-REFERENCE TO RELATED APPLICATIONS

This application claims priority to U.S. Provisional Application Ser. No. 63/463,642 filed May 3, 2023, which is incorporated by reference in their entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down presents new challenge. For example, transistors using nanowire channels have been proposed to achieve increased device density, greater carrier mobility and drive current in a device. As device size reduces, there is a continuous need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-8 are perspective views of various stages of manufacturing a semiconductor device structure, in accordance with some embodiments.

FIGS. 9-25 are cross-sectional side views of various stages of manufacturing the semiconductor device structure taken along cross-section A-A of FIG. 8, in accordance with some embodiments.

FIGS. 11A and 11B illustrate an enlarged view of a portion of the semiconductor device structure of FIG. 11, in accordance with some embodiments.

FIGS. 13A and 14A illustrate an enlarged view of a portion of the semiconductor device structure shown in FIG. 13, in accordance with some embodiments.

FIG. 24A illustrates an enlarged view of a portion of the semiconductor device structure, in accordance with some embodiments.

FIGS. 26-29 illustrate a cross-sectional side view of a semiconductor device structure, in accordance with some alternative embodiments.

FIGS. 30A and 30B are a flowchart of a method for fabricating the semiconductor device according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor devices, and more particularly to field-effect transistors (FETs), such as planar FETs, three-dimensional fin-line FETs (FinFETs), gate-all-around (GAA) devices (e.g., Horizontal Gate All Around (HGAA) FETs, Vertical Gate All Around (VGAA) FETs), vertical FETs, forksheet FETs, or complementary FETs (CFETs). While the embodiments of this disclosure are discussed with respect to GAA devices, implementations of some aspects of the present disclosure may be used in other processes and/or in other devices. A person having ordinary skill in the art will readily understand other modifications that may be made are contemplated within the scope of this disclosure.

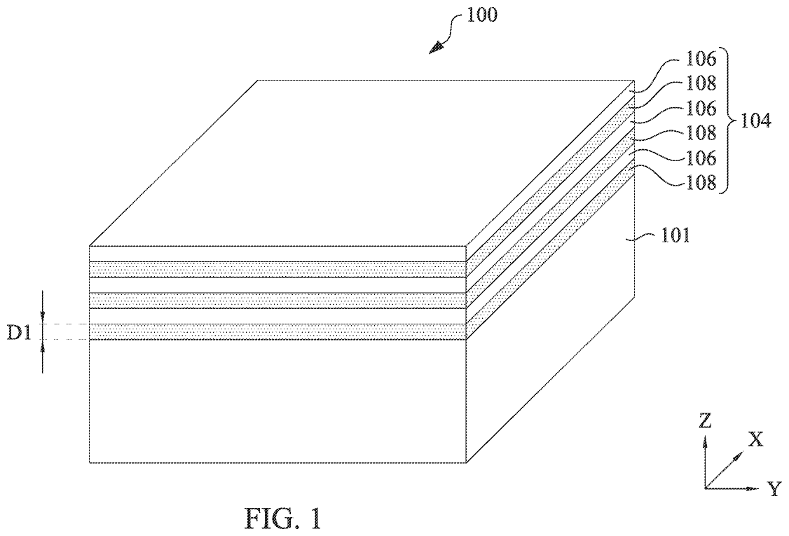

FIGS. 1-30B show exemplary processes for manufacturing a semiconductor device structure 100 according to embodiments of the present disclosure. It is understood that additional operations can be provided before, during, and after processes shown by FIGS. 1-30B, and some of the operations described below can be replaced or eliminated, for additional embodiments of the method. The order of the operations/processes is not limiting and may be interchangeable.

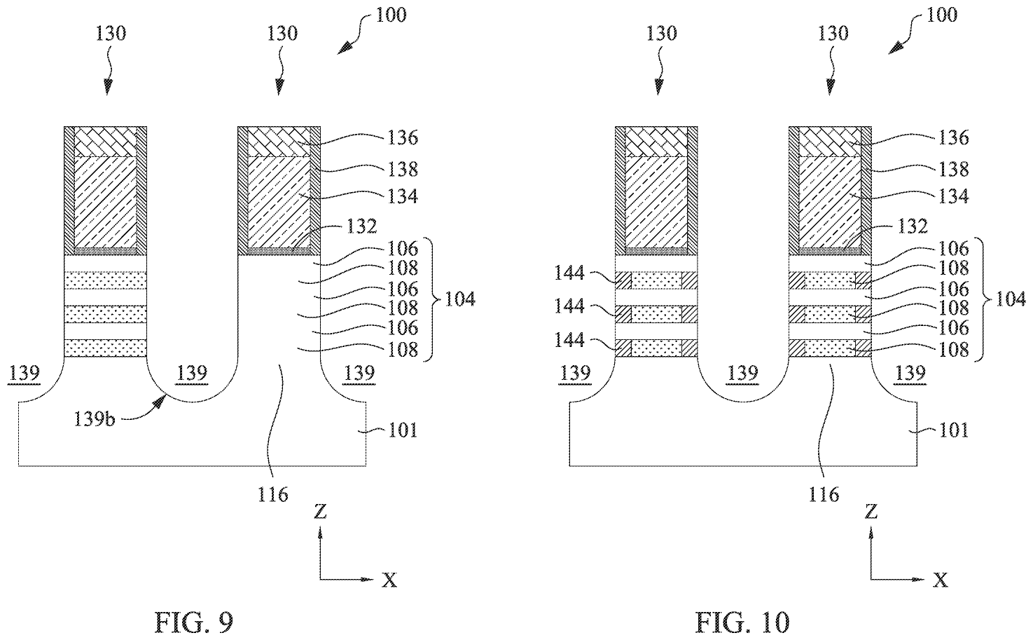

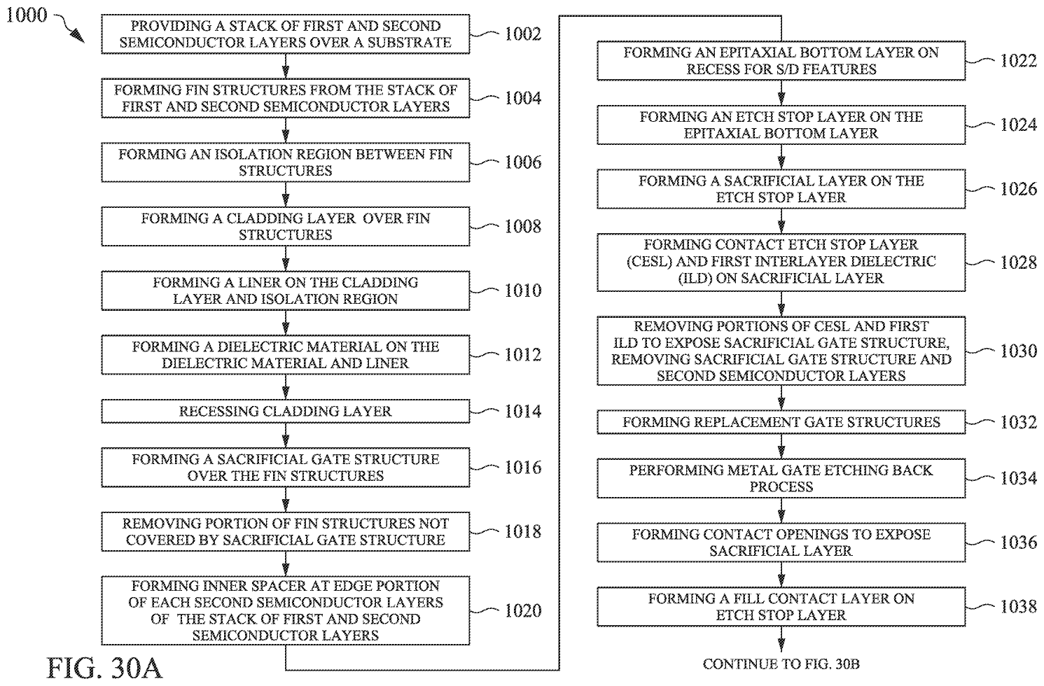

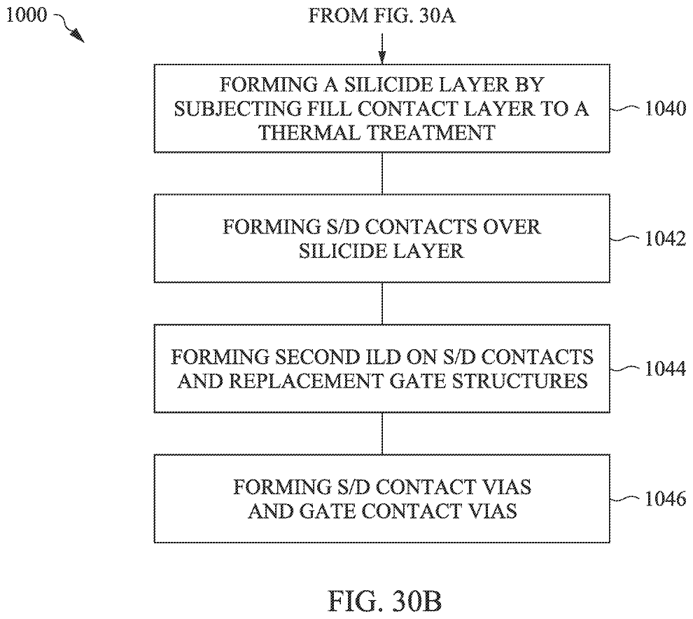

FIGS. 1-8 are perspective views of various stages of manufacturing a semiconductor device structure 100 in accordance with some embodiments. FIGS. 30A and 30B are a flowchart of a method 1000 for fabricating the semiconductor device 100 according to embodiments of the present disclosure. FIGS. 9-25 schematically illustrate the semiconductor device 100 at various stages of fabrication according to the method 1000. It is understood that additional steps can be provided before, during, and/or after the method 1000, and some of the steps described can be replaced, eliminated, and/or moved around for additional embodiments of the method 1000.

At block 1002, the semiconductor device structure 100 including a stack of semiconductor layers 104 formed over a substrate 101 is provided, as shown in FIG. 1. The substrate 101 may be a semiconductor substrate. The substrate 101 may include a crystalline semiconductor material such as, but not limited to, silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In one embodiment, the substrate 101 is made of silicon. In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type impurities). Depending on circuit design, the dopants may be, for example boron for p-type field effect transistors (p-type FETs) and phosphorus for n-type field effect transistors (n-type FETs).

The stack of semiconductor layers 104 includes semiconductor layers made of different materials to facilitate formation of nanosheet channels in a multi-gate device, such as nanosheet FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108, and the first and second semiconductor layers 106, 108 are disposed parallelly with each other. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. In some embodiments, the first semiconductor layers 106 may be made of SiGe having a first Ge concentration range, and the second semiconductor layers 108 may be made of SiGe having a second Ge concentration range that is lower or greater than the first Ge concentration range. In any case, the second semiconductor layers 108 may have a Ge concentration in a range between about 20 at. % (atomic percentage) and 30 at. %.

The thickness of the first semiconductor layers 106 and the second semiconductor layers 108 may vary depending on the application and/or device performance considerations. In some embodiments, each first and second semiconductor layer 106, 108 may have a thickness in a range between about 5 nm and about 30 nm. Each second semiconductor layer 108 may have a thickness that is equal to, less than, or greater than the thickness of the first semiconductor layer 106. In some embodiments, each first semiconductor layer 106 has a thickness in a range between about 10 nm and about 30 nm, and each second semiconductor layer 108 has a thickness in a range between about 5 nm to about 20 nm. The second semiconductor layers 108 may eventually be removed and serve to define a vertical distance between adjacent channels for the semiconductor device structure 100.

The first semiconductor layers 106 or portions thereof may form nanosheet channel(s) of the semiconductor device structure 100 in later fabrication stages. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanosheet channel(s) of the semiconductor device structure 100 may be surrounded by a gate electrode. The semiconductor device structure 100 may include a nanosheet transistor. The nanosheet transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define channels of the semiconductor device structure 100 is further discussed below.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes. While three first semiconductor layers 106 and three second semiconductor layers 108 are alternately arranged as illustrated in FIG. 1, it can be appreciated that any number of first and second semiconductor layers 106, 108 can be formed in the stack of semiconductor layers 104, depending on the predetermined number of nanosheet channels for each FET. For example, the number of first semiconductor layers 106, which is the number of channels, may be between 2 and 8.

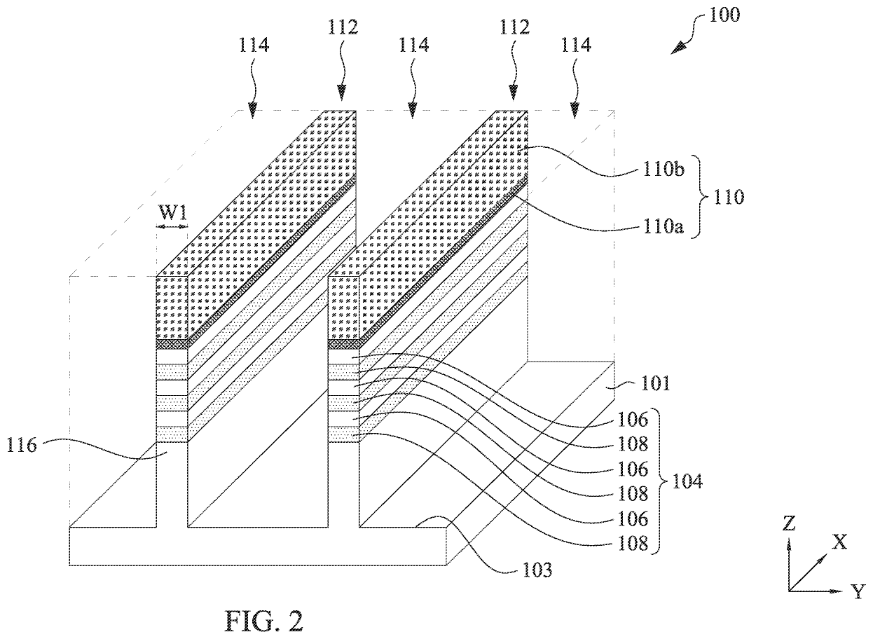

At block 1004, fin structures 112 are formed from the stack of semiconductor layers 104, as shown in FIG. 2. Each fin structure 112 has an upper portion including the semiconductor layers 106, 108 and a well portion 116 formed from the substrate 101. A mask structure 110 is formed over the stack of semiconductor layers 104 prior to forming the fin structures 112. The mask structure 110 may include a pad layer 110a and a hard mask 110b. The pad layer 110a may be an oxygen-containing layer, such as a SiO₂ layer. The hard mask 110b may be a nitrogen-containing layer, such as a Si₃N₄ layer. The mask structure 110 may be formed by any suitable deposition process, such as chemical vapor deposition (CVD) process.

The fin structures 112 may be formed by patterning the mask structure 110 using one or more photolithography processes and etching processes. The etching process can include dry etching, wet etching, reactive ion etching (RIE), and/or other suitable processes. The photolithography process may include double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. As an example of one multi-patterning process, a sacrificial layer may be formed over a substrate and patterned using a photolithography process. Spacers are formed alongside the patterned sacrificial layer using a self-aligned process. The sacrificial layer is then removed, and the remaining spacers may then be used to pattern the fin structures 112. In any case, the one or more etching processes form trenches 114 in unprotected regions through the mask structure 110, through the stack of semiconductor layers 104, and into the substrate 101, thereby leaving the plurality of extending fin structures 112. A width W1 of the fin structures 112 along the Y direction may be in a range between about 1.5 nm and about 44 nm, for example about 2 nm to about 6 nm. The trenches 114 may be etched using a dry etch (e.g., RIE), a wet etch, and/or combination thereof. While two fin structures 112 are shown, the number of the fin structures is not limited to two.

FIG. 2 further illustrates the fin structures 112 having substantially vertical sidewalls, such that width of the fin structures 112 are substantially similar and each of the first and second semiconductor layers 106, 108 in the fin structures 112 is rectangular in shape. In some embodiments, the fin structures 112 may have tapered sidewalls, such that a width of each of the fin structures 112 continuously increases in a direction towards the substrate 101. In such cases, each of the first and second semiconductor layers 106, 108 in the fin structures 112 may have a different width and be trapezoidal in shape.

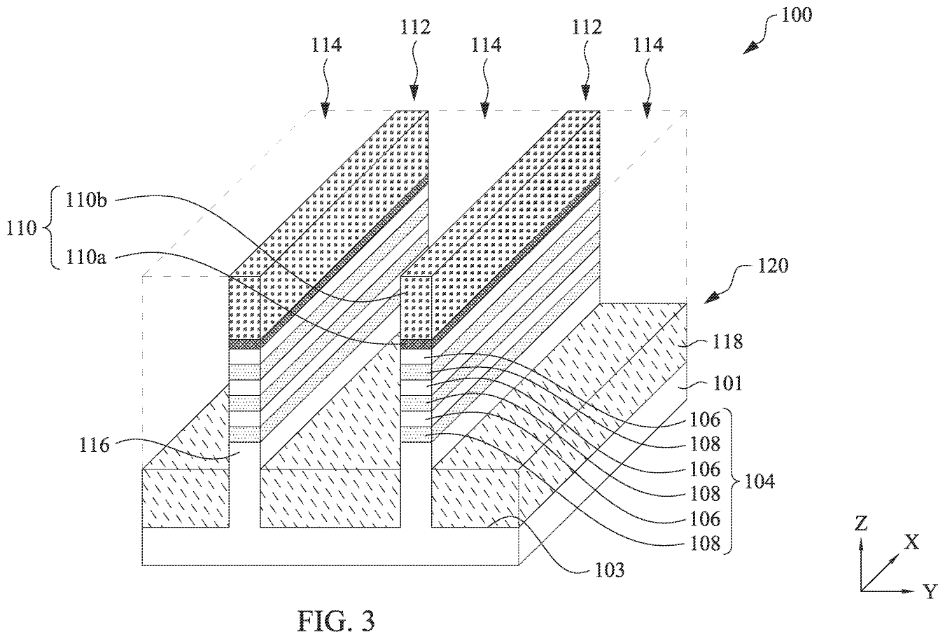

At block 1006, after the fin structures 112 are formed, an insulating material 118 is formed in the trenches 114 between the fin structures 112, as shown in FIG. 3. The insulating material 118 fills the trenches 114 between neighboring fin structures 112 until the fin structures 112 are embedded in the insulating material 118. Then, a planarization operation, such as a chemical mechanical polishing (CMP) process and/or an etch-back process, is performed to expose the top of the fin structures 112. The insulating material 118 may be made of silicon oxide, silicon nitride, silicon oxynitride (SiON), SiOCN, SiCN, fluorine-doped silicate glass (FSG), a low-k dielectric material, or any suitable dielectric material. The insulating material 118 may be formed by any suitable method, such as low-pressure chemical vapor deposition (LPCVD), plasma enhanced CVD (PECVD) or flowable CVD (FCVD).

Thereafter, the insulating material 118 is recessed to form an isolation region 120. After recessing, portions of the fin structures 112, such as the stack of semiconductor layers 104, may protrude from between neighboring isolation regions 120. The isolation regions 120 may have top surfaces that are flat as illustrated, convex, concave, or a combination thereof. The recess of the insulating material 118 reveals the trenches 114 between the neighboring fin structures 112. The isolation region 120 may be formed using a suitable process, such as a dry etching process, a wet etching process, or a combination thereof. In one embodiment, the isolation regions 120 are formed using dilute hydrofluoric acid (dHF), which is selective to the insulating material 118 over the stack of semiconductor layers 104. Upon completion of recessing, a top surface of the insulating material 118 may be level with or below a surface of the second semiconductor layers 108 in contact with the well portion 116 formed from the substrate 101.

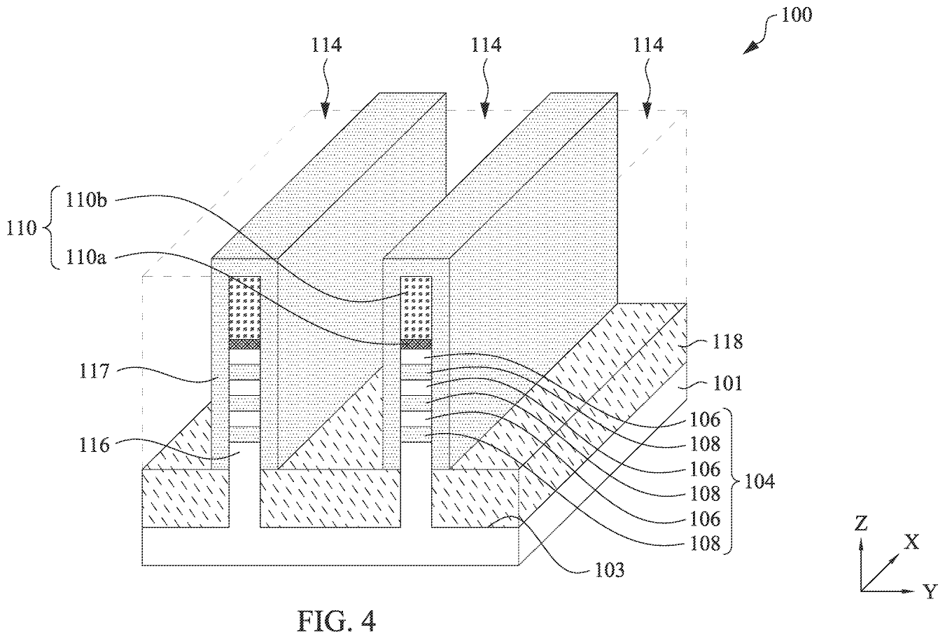

At block 1008, a cladding layer 117 is formed by an epitaxial process over exposed portion of the fin structures 112, as shown in FIG. 4. In some embodiments, a semiconductor liner (not shown) may be first formed over the fin structures 112, and the cladding layer 117 is then formed over the semiconductor liner. The semiconductor liner may be diffused into the cladding layer 117 during the formation of the cladding layer 117. In either case, the cladding layer 117 is in contact with the stack of semiconductor layers 104. In some embodiments, the cladding layer 117 and the second semiconductor layers 108 include the same material having the same etch selectivity. For example, the cladding layer 117 and the second semiconductor layers 108 may be or include SiGe. The cladding layer 117 and the second semiconductor layers 108 may be removed subsequently to create space for the subsequently formed gate electrode layer.

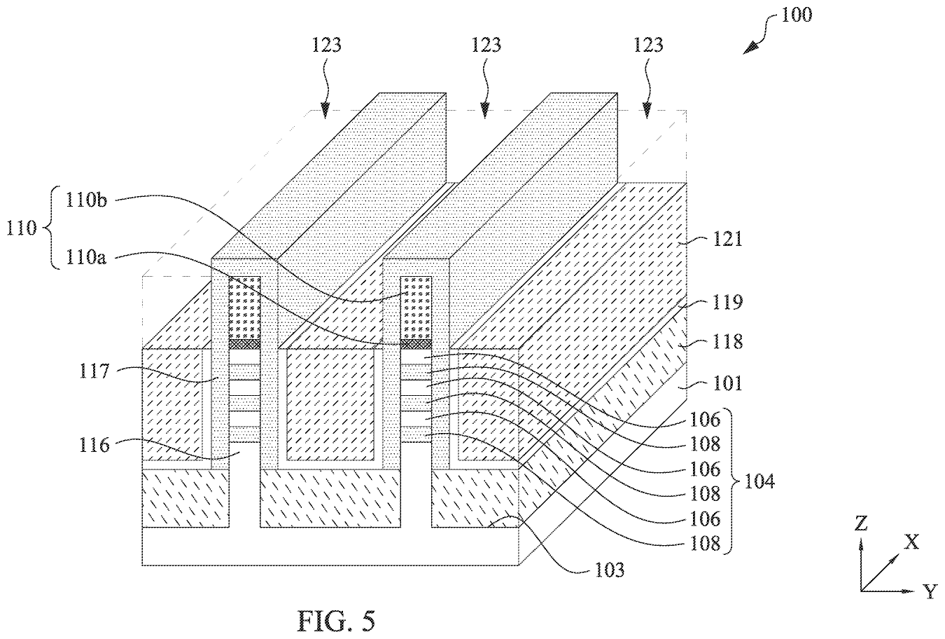

At block 1010, a liner 119 is formed on the cladding layer 117 and the top surface of the insulating material 118, as shown in FIG. 5. The liner 119 may include a material having a k value lower than 7, such as SiO₂, SiN, SiCN, SiOC, or SiOCN. The liner 119 may be formed by a conformal process, such as an ALD process. A dielectric material 121 is then formed in the trenches 114 (FIG. 4) and on the liner 119. The dielectric material 121 may be an oxygen-containing material, such as an oxide, formed by FCVD. The oxygen-containing material may have a k value less than about 7, for example less than about 3. A planarization process, such as a CMP process, may be performed to remove portions of the liner 119 and the dielectric material 121 formed over the fin structures 112. The portion of the cladding layer 117 disposed on the hard mask 110b is exposed after the planarization process.

Next, the liner 119 and the dielectric material 121 are recessed to the level of the topmost first semiconductor layer 106. For example, in some embodiments, after the recess process, the top surfaces of the liner 119 and the dielectric material 121 may be level with a top surface of the uppermost first semiconductor layer 106. The recess processes may be selective etch processes that do not substantially affect the semiconductor material of the cladding layer 117. As a result of the recess process, trenches 123 are formed between the fin structures 112.

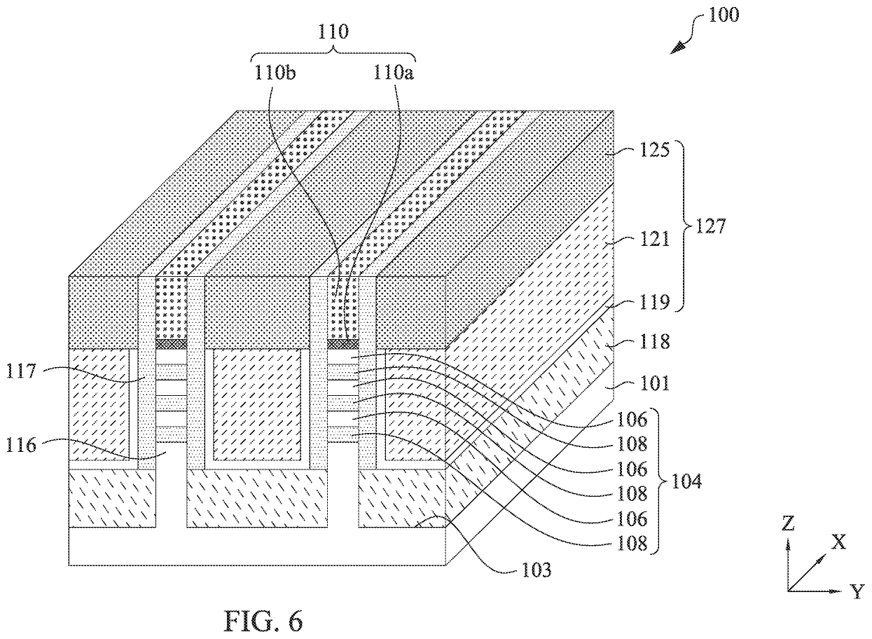

At block 1012, a dielectric material 125 is formed in the trenches 123 (FIG. 5) and on the dielectric material 121 and the liner 119, as shown in FIG. 6. The dielectric material 125 may include SiO, SiN, SiC, SiCN, SION, SiOCN, AIO, AlN, AlON, ZrO, ZrN, ZrAlO, HfO, or other suitable dielectric material. In some embodiments, the dielectric material 125 includes a high-k dielectric material (e.g., a material having a k value greater than 7). The dielectric material 125 may be formed by any suitable process, such as a CVD, PECVD, FCVD, or ALD process. A planarization process, such as a CMP process, is performed until the hard mask 110b of the mask structure 110 is exposed. The planarization process removes portions of the dielectric material 125 and the cladding layer 117 disposed over the mask structure 110. The liner 119, the dielectric material 121, and the dielectric material 125 together may be referred to as a dielectric feature 127 or a hybrid fin. The dielectric feature 127 serves to separate subsequent formed source/drain (S/D) epitaxial features and adjacent gate electrode layers.

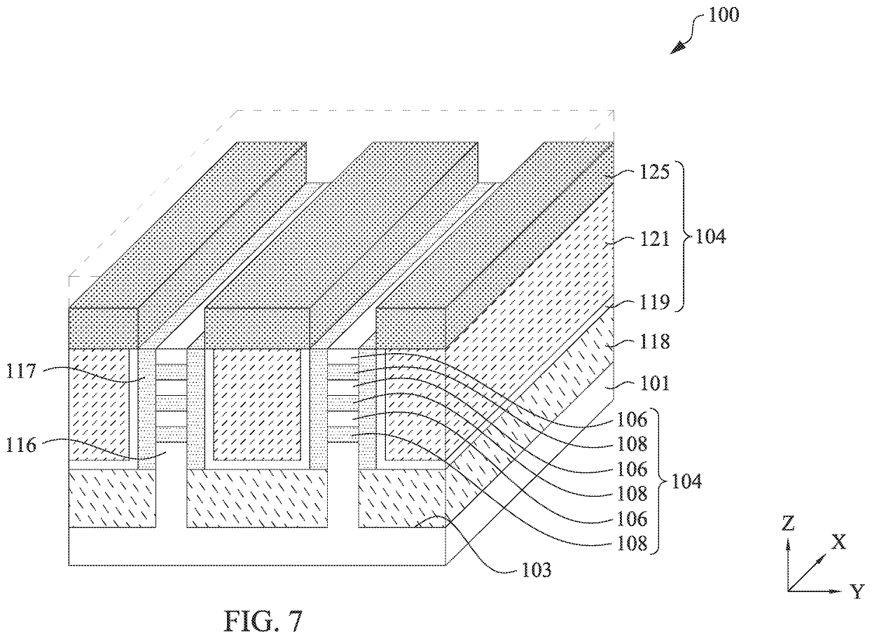

At block 1014, the cladding layers 117 are recessed, and the mask structures 110 are removed, as shown in FIG. 7. The recess of the cladding layers 117 may be performed by any suitable process, such as dry etch, wet etch, or a combination thereof. The recess process may be controlled so that the remaining cladding layers 117 are substantially at the same level as the top surface of the uppermost first semiconductor layer 106 in the stack of semiconductor layers 104. The etch process may be a selective etch process that does not substantially affect the dielectric material 125. The removal of the mask structures 110 may be performed by any suitable process, such as dry etch, wet etch, or a combination thereof.

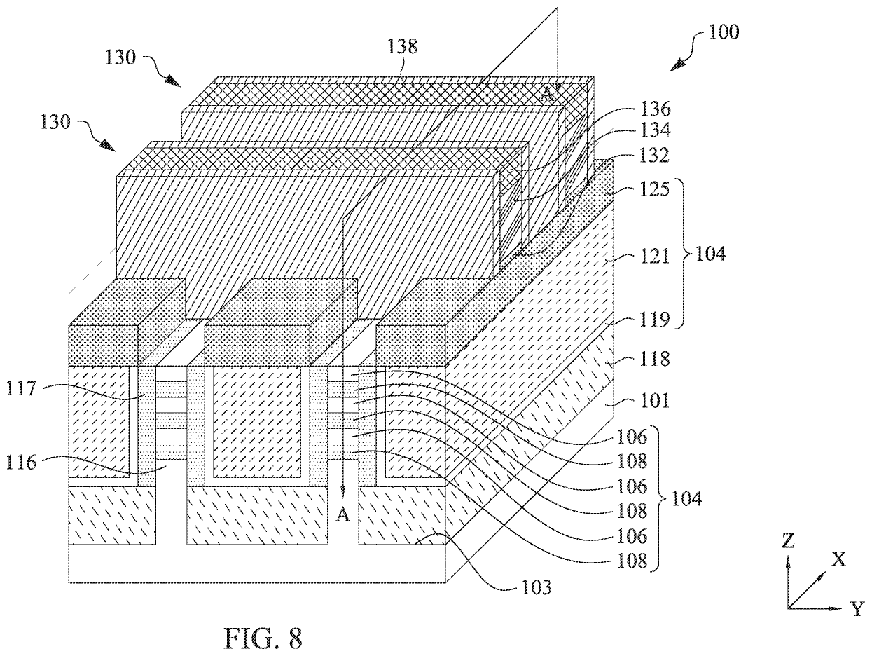

At block 1016, one or more sacrificial gate structures 130 (only two is shown) are formed over the semiconductor device structure 100, as shown in FIG. 8. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, followed by pattern and etch processes. For example, the pattern process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etch (e.g., RIE), wet etch, other etch methods, and/or combinations thereof.

By patterning the sacrificial gate structure 130, the stacks of semiconductor layers 104 of the fin structures 112 are partially exposed on opposite sides of the sacrificial gate structure 130. The portions of the fin structures 112 that are covered by the sacrificial gate electrode layer 134 of the sacrificial gate structure 130 serve as channel regions for the semiconductor device structure 100. The fin structures 112 that are partially exposed on opposite sides of the sacrificial gate structure 130 define source/drain (S/D) regions for the semiconductor device structure 100. In some cases, some S/D regions may be shared between various transistors. For example, various one of the S/D regions may be connected together and implemented as multiple functional transistors. While two sacrificial gate structures 130 are shown, more or less sacrificial gate structures 130 may be arranged along the X direction in some embodiments.

Next, gate spacers 138 are formed on sidewalls of the sacrificial gate structures 130. The gate spacers 138 may be formed by first depositing a conformal layer that is subsequently etched back to form sidewall gate spacers 138. For example, a spacer material layer can be disposed conformally on the exposed surfaces of the semiconductor device structure 100. The conformal spacer material layer may be formed by an ALD process. Subsequently, anisotropic etch is performed on the spacer material layer using, for example, RIE. During the anisotropic etch process, most of the spacer material layer is removed from horizontal surfaces, such as the tops of the fin structures 112, the cladding layer 117, the dielectric material 125, leaving the gate spacers 138 on the vertical surfaces, such as the sidewalls of sacrificial gate structures 130. The gate spacer 138 may be made of a dielectric material such as silicon oxide, silicon nitride, silicon carbide, silicon oxynitride, SiCN, silicon oxycarbide, SiOCN, and/or combinations thereof.

In some embodiments where the cladding layers 117 and the dielectric features 127 are not present, portions of the sacrificial gate structures 130 and the gate spacers 138 are formed on the insulating material 118, and gaps are formed between exposed portions of the fin structures 112.

FIGS. 9-30 are cross-sectional side views of various stages of manufacturing the semiconductor device structure 100 taken along cross-section A-A of FIG. 8, in accordance with some embodiments. Cross-section A-A is in a plane of the fin structure 112 along the X direction. At block 1018, exposed portions of the stacks of semiconductor layers 104 of the fin structures 112, exposed portions of the cladding layers 117, and a portion of the exposed dielectric material 125 not covered by the sacrificial gate structures 130 and the gate spacers 138 are removed to form recess 139 for the S/D features, as shown in FIG. 9. The removal of the layers may be done by using one or more suitable etch processes, such as dry etch, wet etch, or a combination thereof. The one or more etch processes may be performed until the well portions 116 are exposed. The exposed portions of the fin structures 112 may be recessed to a level at the bottom surface of the second semiconductor layer 108 in contact with the well portion 116 of the substrate 101. In some embodiments, the etch process is performed such that the bottom 139b of the recess 139 is at an elevation below an interface defined by the bottommost second semiconductor layer 108 and the well portion 116.

At block 1020, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etching process. In cases where the second semiconductor layers 108 are made of SiGe and the first semiconductor layers 106 are made of silicon and/or SiGe having lower germanium concentration than the second semiconductor layers 108, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers (or so-called inner spacer) 144, as shown in FIG. 10. The dielectric spacers 144 may be made of SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

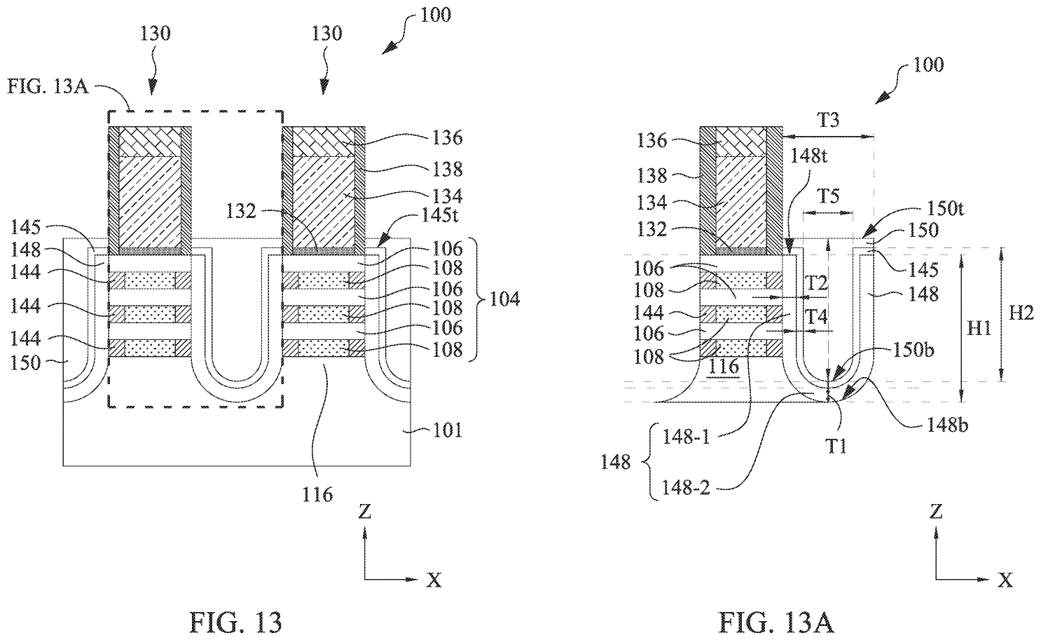

At block 1022, a first portion of source/drain (S/D) feature is formed in the S/D regions between the neighboring sacrificial gate structures 130. As will be discussed below, the S/D epitaxial feature at this stage includes an epitaxial bottom layer 148, an etch stop layer 145 formed on the epitaxial bottom layer 148, and a sacrificial layer 150 formed on the etch stop layer 145, as shown in FIG. 13. The shape of the S/D epitaxial features is confined by the dielectric feature 127 (FIG. 8). The S/D epitaxial features may be the S/D regions. For example, one of a pair of S/D epitaxial features located on one side of the sacrificial gate structures 130 may be a source region, and the other of the pair of S/D epitaxial features located on the other side of the sacrificial gate structures 130 may be a drain region. A pair of S/D epitaxial features includes a source epitaxial feature and a drain epitaxial feature connected by the channel layers (i.e., the first semiconductor layers 106). In this disclosure, a source and a drain are interchangeably used, and the structures thereof are substantially the same.

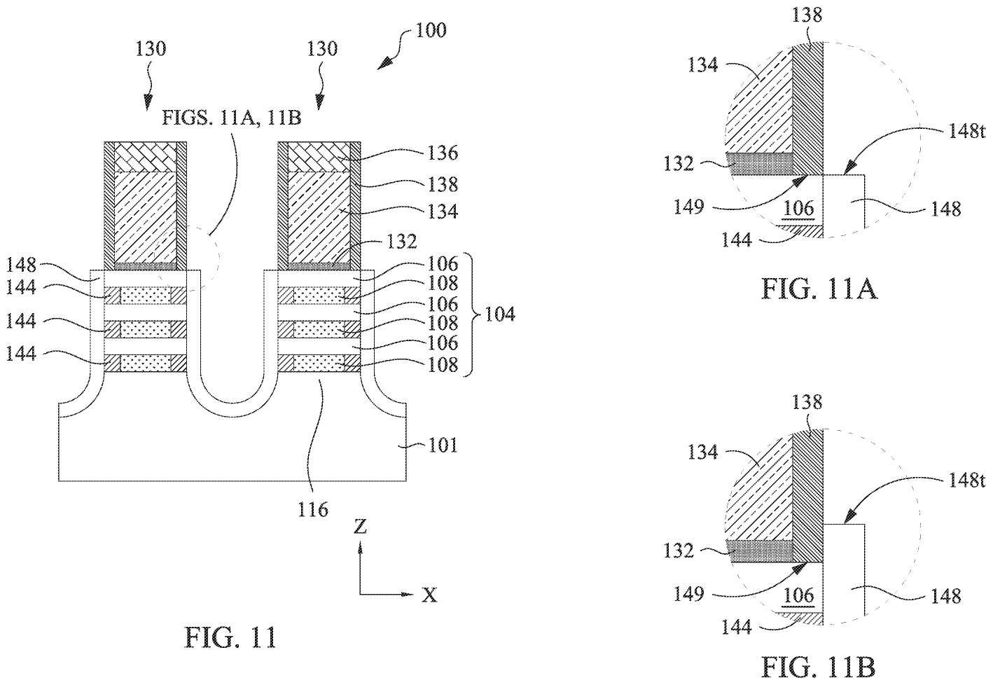

Referring back to FIG. 11, the epitaxial bottom layer 148 is formed on exposed surfaces of the recess 139 (FIG. 10). The epitaxial bottom layer 148 is selectively formed on a semiconductor surface of the first semiconductor layers 106 and the well portions 116, while a dielectric surface of the sacrificial gate structures 130 (e.g., mask layers 136 and gate spacers 148) remains exposed. In some embodiments, a portion of the epitaxial bottom layer 148 may extend to cover the surface of the dielectric spacers 144. The epitaxial bottom layer 148 may have a generally U-shaped profile extending in a direction across sidewall surfaces of the first semiconductor layers 106. The epitaxial bottom layer 148 may serve as a leakage barrier layer to prevent possible diffusion of subsequent metallic elements into the gate area. The epitaxial bottom layer 148 may include or be formed of silicon, germanium, or silicon germanium. Depending on the conductivity type of the S/D features to be grown thereon, n-type or p-type dopants may be added. For example, the epitaxial bottom layer 148 at a n-type device region may be silicon doped with n-type dopants, such as phosphorous, antimony, or arsenic, and the epitaxial bottom layer 148 at a p-type device region may be silicon doped with p-type dopants, such as boron or gallium. Exemplary epitaxial bottom layers 148 may include boron-doped silicon (Si: B), phosphorous doped silicon (Si: P), gallium doped silicon (Si: Ga), boron-doped germanium (Ge: B), boron-doped silicon germanium (SiGe: B), or gallium-doped silicon germanium (SiGe: Ga).

In cases where silicon germanium is used for p-type S/D features, the epitaxial bottom layer 148 may have an atomic percentage of Ge in a range between about 0 at. % and 80 at. %, such as about 40 at. % to about 60 at. %, for channel stress boosting with quality. The epitaxial bottom layer 148 may have a dopant concentration in a range of about 5E19 atoms/cm³ and about 5E21 atoms/cm³. The epitaxial bottom layer 148 used at the n-type S/D features may have a dopant concentration in a range of about 5E19 atoms/cm³ and about 5E21 atoms/cm³. In any case, the dopants may be evenly distributed in the epitaxial bottom layer 148 (e.g., constant distribution) or gradually distributed along the thickness of the epitaxial bottom layer 148 (e.g., gradient distribution). For example, the dopants in the epitaxial bottom layer 148 may have a first dopant concentration at and/or near the surface, and a second dopant concentration at an interface of the epitaxial bottom layer 148 and the first semiconductor layer 106, wherein the first dopant concentration is greater than the second dopant concentration. Alternatively, the dopants may be controlled so that the first dopant concentration is lower than the second dopant concentration.

In some embodiments, the epitaxial bottom layer 148 may be deposited such that a top of the epitaxial bottom layer 148 may be at an elevation higher or equal to a top of the topmost first semiconductor layers 106. FIGS. 11A and 11B illustrate an enlarged view of a portion of the semiconductor device structure 100 of FIG. 11, in accordance with some embodiments. In the embodiment shown in FIG. 11A, the epitaxial bottom layer 148 is formed to have a top surface 148t at an elevation that is substantially the same as an interface 149 defined by the gate spacer 138 and the first semiconductor layer 106. In the embodiment shown in FIG. 11B, the epitaxial bottom layer 148 is formed to have a top surface 148t at an elevation that is higher than the interface 149 defined by the gate spacer 138 and the first semiconductor layer 106.

The epitaxial bottom layer 148 may be formed using any suitable deposition process, such as CVD, cyclic deposition etch (CDE) epitaxy process, selective etch growth (SEG) process, ALD, PEALD, molecular beam epitaxy (MBE), or any combination thereof. In some embodiments, the first semiconductor layers 106 may be exposed to silicon-containing precursor(s) and n-type or p-type dopant-containing precursor(s) in a process chamber to form the epitaxial bottom layer 148. The process conditions of the growth process are configured in accordance with the crystal planes of the first semiconductor layer 106 and the substrate 101 to promote formation of the epitaxial bottom layer 148. The dopants in the epitaxial bottom layers 148 may be added during the formation of the epitaxial bottom layers 148, and/or after the formation of the epitaxial bottom layers 148 by an implantation process.

In one exemplary embodiment where the epitaxial bottom layer 148 includes boron-doped silicon germanium, the epitaxial bottom layer 148 may be formed by heating the semiconductor device structure 100 to a temperature of about 400 degrees Celsius to about 750 degrees Celsius, such as about 520 degrees Celsius to about 620 degrees Celsius, maintaining chamber pressure at about 10 Torr to about 300 Torr, such as about 20 Torr to about 80 Torr, and exposing the exposed surfaces of the semiconductor device structure 100 to a gas mixture including at least a silicon-containing precursor, a germanium-containing precursor, and a boron-containing precursor. Suitable silicon-containing precursor may include, but is not limited to, silane (SiH₄), disilane (Si₂H₆), trisilane (Si₃H₈), tetrasilane (Si₄H₁₀), dimethylsilane ((CH₃)₂SiH₂), methylsilane (SiH(CH₃)₃), dichlorosilane (SiH₂Cl₂, DCS), trichlorosilane (SiHCl₃, TCS), or the like. Suitable germanium-containing precursor may include, but is not limited to, germane (GeH₄), germanium tetrachloride (GeCl₄), digermane (Ge₂H₆), trigermane (Ge₃H₈), or germylsilane (GeH₆Si) or the like. Suitable gases for the boron-containing precursor may include, but are not limited to, borane (BH₃), diborane (B₂H₆), boron trichloride (BCl₃), triethyl borate (TEB), borazine (B₃N₃H₆), or an alkyl-substituted derivative of borazine, or the like. A diluent/carrier gas, such as hydrogen (H₂) and/or argon (Ar), may be used along with the precursors for the epitaxial bottom layer 148. In one embodiment, the epitaxial bottom layer 148 is formed by DCS, GeH₄, and B₂H₆. In one embodiment, the epitaxial bottom layer 148 is formed by DCS, GeH₄, and BCl₃. In some cases, the epitaxial bottom layer 148 may be deposited by a deposition-etch-deposition process for improve void-free gap-filling. In such cases, an etch gas, such as HCl or Cl₂ may be further introduced into the reaction chamber. The formation of the epitaxial bottom layer 148 may be performed in a CVD based reaction chamber. The epitaxial bottom layer 148 using silicon or silicon germanium allows subsequent etch stop layer 145 to be directly formed thereon.

If desired, after the epitaxial bottom layer 148 is formed, an etch back process may be performed to prepare the epitaxial bottom layer 148 with a surface profile suitable for accommodating the subsequent etch stop layer 145. The etch back process may be a dry etch, a wet etch, or a combination thereof. In some embodiments, the etch back process is a wet etch process using NH₄OH, HF or diluted HF, deionized (DI) water, tetramethylammonium hydroxide (TMAH), other suitable solution, or a combination thereof. In some embodiments, the etch back process may be a standard clean-2 (SC2) followed by a standard clean-1 (SC1), where the SC2 is a mixture of DI water, hydrochloric (HCl) acid, and hydrogen peroxide (H₂O₂), and the SC1 is a mixture of DI water, NH₄OH, and H₂O₂. In some embodiments, an isopropyl alcohol (IPA) may be used after the SC1. Other suitable wet etch process, such as an APM process, which includes at least water (H₂O), ammonium hydroxide (NH₄OH), and hydrogen peroxide (H₂O₂), a HPM process, which includes at least H₂O, H₂O₂, and hydrogen chloride (HCl), a SPM process (also known as piranha clean), which includes at least H₂O₂ and sulfuric acid (H₂SO₄), or any combination thereof, may also be used.

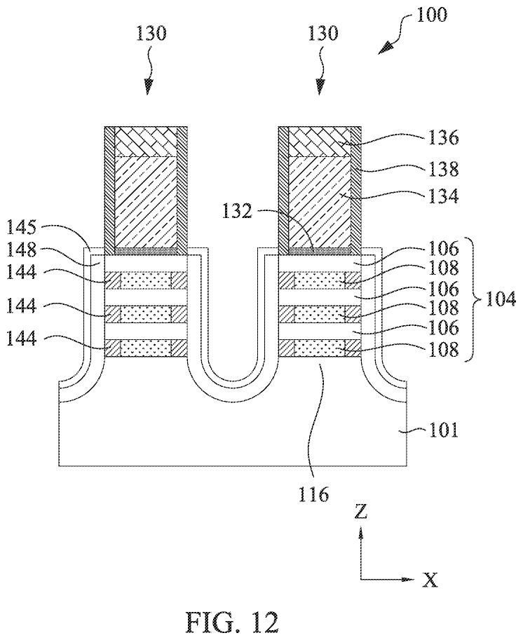

At block 1024, a second portion of the S/D feature, i.e., the etch stop layer 145, is formed on the epitaxial bottom layer 148, as shown in FIG. 12. The etch stop layer 145 may be a conformal layer formed on the exposed surfaces of the epitaxial bottom layer 148. The etch stop layer 145 protects the underlying epitaxial bottom layers 148 during formation of the subsequent metal contact. Therefore, the etch stop layer 145 can help to control recess shape during S/D contact formation and to enlarge contact area for the S/D contacts. The etch stop layer 145 may include a semiconductor material, and may be selected from the material used for the epitaxial bottom layer 148, such as silicon or silicon germanium. The etch stop layer 145 and the epitaxial bottom layer 148 may include a material that is chemically different than one another. Likewise, depending on the conductivity type of the S/D features to be grown thereon, n-type or p-type dopants may be added. For example, the epitaxial bottom layer 148 at a n-type device region may be silicon doped with n-type dopants, such as phosphorous, antimony, or arsenic, and the etch stop layer 145 at a p-type device region may be silicon doped with p-type dopants, such as boron or gallium. In some embodiments, the etch stop layer 145 is boron-doped silicon (Si: B). In some embodiments, the etch stop layer 145 may include be formed of silicon germanium. In such cases, the etch stop layer 145 may have a Ge concentration lower than the Ge concentration of the epitaxial bottom layer 148. For example, the etch stop layer 145 may have an atomic percentage of Ge in a range between about 0.5 at. % and 30 at. %, such as about 5 at. % to about 15 at. %. The etch stop layer 145 may be deposited using the similar deposition technique as the epitaxial bottom layer 148.

The etch stop layer 145 may have a dopant concentration greater than the dopant concentration of the epitaxial bottom layer 148. In one exemplary embodiment where boron-doped silicon is used for the p-type S/D features, the etch stop layer 145 may have a dopant concentration in a range of about 5E20 atoms/cm³ and about 1E22 atoms/cm³. The etch stop layer 145 may be deposited using the same deposition process as the epitaxial bottom layer 148.

In some embodiments, the etch stop layer 145 is further subjected to an oxidation process to oxidize an outer portion of the etch stop layer 145. The oxidation process converts the outer portion of the etch stop layer 145 to a native oxide layer, which can enhance etching reaction at the surface of the etch stop layer 145. The native oxide layer helps the etch stop layer 145 with better etching profile control at a later stage when removing the subsequent sacrificial layer 150 for the S/D contact formation. In cases where the etch stop layer 145 is formed of silicon, germanium, or silicon germanium, the etch stop layer 145 may have the outer portion in the form of either (Si, Ge)O₂ or germanium oxide (e.g., GeO₂), and an inner portion containing silicon, germanium, or silicon germanium. The oxidation process may be thermal oxidation process, a rapid thermal oxidation (RTO) process, an in-situ stream generation (ISSG) process, or an enhanced in-situ stream generation (EISSG) process. In one example, the etch stop layer 145 is formed by subjecting the etch stop layer 145 to a rapid thermal anneal (RTA) in an oxygen-containing environment. The thermal oxidation may be performed at a temperature of about 600 degrees Celsius to about 1100 degrees Celsius, for a time span of about 10 seconds to about 30 seconds. The temperature and time span of the oxidation may contribute to the thickness of the etch stop layer 145. For example, higher temperatures and longer oxidation time spans may result in a thicker etch stop layer 145. The etch stop layer 145 may have a thickness of about 0.01 nm to about 5 nm, such as about 0.05 to about 1 nm, which varies depending on the thickness and oxidation of the etch stop layer 145.

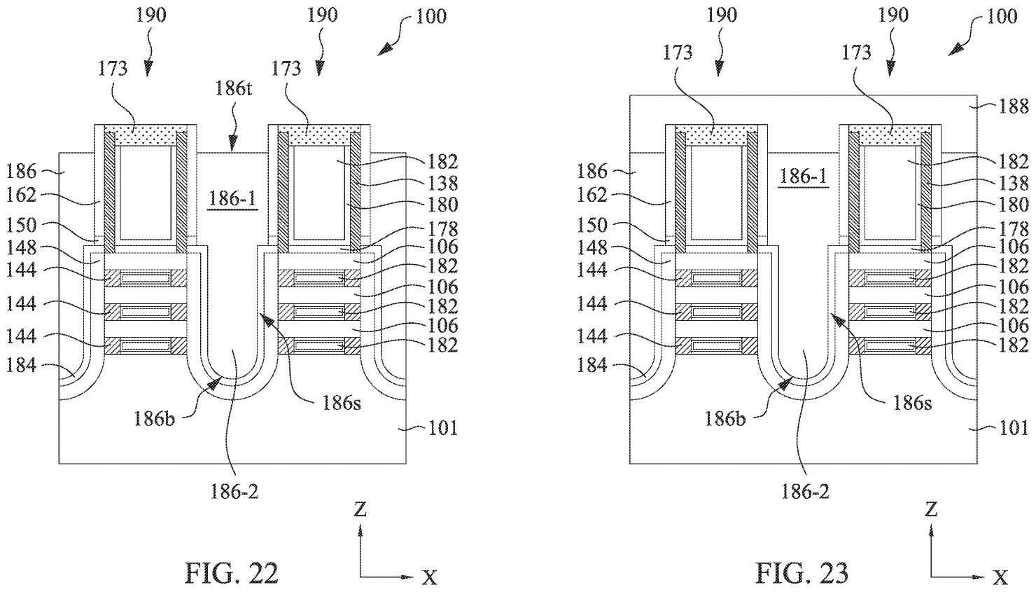

At block 1026, a third portion of the S/D feature, i.e., the sacrificial layer 150, is formed on the etch stop layer 145, as shown in FIG. 13. The sacrificial layer 150 fills in the remaining space in the recess 139 (FIG. 10) and above the top surface of the etch stop layer 145 until a predetermined height is achieved. The etch stop layer 145 is therefore embedded in the S/D feature. A portion of the sacrificial layer 150 is formed on the top surface 145t of the etch stop layer 145, resulting in the sacrificial layer 150 with a T-shaped or bar-shaped profile. The material of the sacrificial layer 150 is selected so that it provides high etch selectivity with respect to the etch stop layer 145. The sacrificial layer 150 is to be removed prior to formation of the subsequent metal contact. The etch selectivity between the sacrificial layer 150 and the etch stop layer 145 prevents etchants used during subsequent removal of the sacrificial layer 150 from removing the etch stop layer 145 and damage the underlying epitaxial bottom layer 148. The space created due to removal of the sacrificial layer 150 allows the subsequent S/D contacts (186, FIG. 22) to form with additional contact area, which improves the device performance.

The sacrificial layer 150 may include a semiconductor material, and may be selected from the material used for the epitaxial bottom layer 148, such as silicon or silicon germanium. The sacrificial layer 150 may include a material that is chemically different than the etch stop layer 145. In some embodiments, the sacrificial layer 150 may include or be formed of silicon germanium. In such cases, the sacrificial layer 150 may have a Ge concentration greater than the Ge concentration of the etch stop layer 145. In some embodiments, the sacrificial layer 150 has a Ge concentration greater than the Ge concentration of the epitaxial bottom layer 148. For example, the etch stop layer 145 may have an atomic percentage of Ge in a range between about 40 at. % and 80 at. %, such as about 50 at. % to about 60 at. %. The sacrificial layer 150 may be deposited using the same deposition process as the epitaxial bottom layer 148. In some embodiments, the epitaxial bottom layer 148, the etch stop layer 145, and the sacrificial layer 150 are sequentially formed in-situ in the same process chamber.

FIG. 13A illustrates an enlarged view of a portion of the semiconductor device structure 100 shown in FIG. 13, in accordance with some embodiments. In one embodiment, the epitaxial bottom layer 148 may have a height H1 measuring from the top surface 148t to a bottom surface 148b of the epitaxial bottom layer 148. The epitaxial bottom layer 148 may have an upper portion 148-1 and a bottom portion 148-2. The upper portion 148-1 may refer to the portion of the epitaxial bottom layer 148 disposed above a bottom surface of the bottommost first semiconductor layer 106. The lower portion 148-2 may refer to the portion of the epitaxial bottom layer 148 disposed below the bottom surface of the bottommost first semiconductor layer 106. The upper portion 148-1 may have a thickness T1 and the bottom portion 148-2 may have a thickness T2 less than the thickness T1. The difference between the thickness T1 and the thickness T2 may be due to the etch back process performed on the epitaxial bottom layer 148. In some embodiments, the thickness T1 of the epitaxial bottom layer 148 may be about 10% to about 40% of the height H1 of the epitaxial bottom layer 148.

The upper portion 148-1 of the epitaxial bottom layer 148, the etch stop layer 145, and the sacrificial layer 150 may have a combined lateral thickness T3 measuring at an elevation of the first semiconductor layer 106. In some embodiments, the thickness T2 may be about 5% to about 20% of the combined thickness T3. The etch stop layer 145 may have a thickness T4, and the thickness T4 may be about 5% to about 10% of the combined thickness T3. The sacrificial layer 150 may have a thickness T5, and the thickness T5 may be about 10% to about 20% of the combined thickness T3. The sacrificial layer 150 may have a height H2 measuring from a top surface 150t to a bottom surface 150b of the sacrificial layer 150. The bottom surface 150b is an interface defined by the sacrificial layer 150 and the etch stop layer 145. The height H2 of the sacrificial layer 150 may be about 50% to about 80% of the height H1 of the epitaxial bottom layer 148.

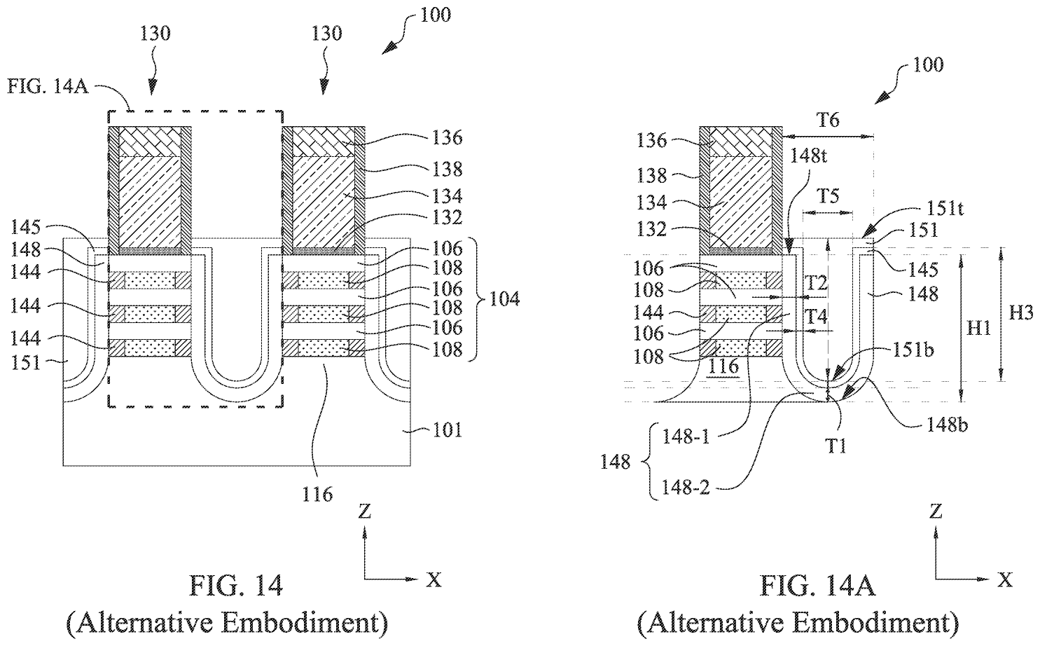

In some alternative embodiments, instead of a semiconductor material, the sacrificial layer 150 may include or be formed of a dielectric material. In such embodiments, the epitaxial bottom layer 148 and the etch stop layer 145 are formed of a semiconductor material, and the sacrificial layer 150 is formed of a dielectric material. The epitaxial bottom layer 148 and the etch stop layer 145 may be epitaxially deposited, in-situ, on exposed surfaces of the recess 139 (FIG. 10), followed by the dielectric sacrificial layer depositing on the etch stop layer 145. The use of a dielectric material as the sacrificial layer provides better thermal stability when compared to the sacrificial layer using a semiconductor material or silicon germanium with high Ge concentration. FIG. 14 illustrates the semiconductor device structure 100 in accordance with some alternative embodiments. In this embodiment, after the etch stop layer 145 is formed, a sacrificial layer 151 is formed on the etch stop layer 145. The sacrificial layer 151 may be an oxygen-containing layer, such as silicon oxide, silicon oxynitride (SiON), silicon oxycarbide (SiOC), silicon oxycarbonitride (SiOCN), or the like. In some embodiments, the sacrificial layer 151 may have an atomic percentage of oxygen in a range between about 20 at. % and 80 at. %, an atomic percentage of carbon in a range between about 0 at. % and about 20 at. %, and an atomic percentage of nitrogen in a range between about 0 at. % and about 40 at. %. The sacrificial layer 151 may be formed by an ALD, PECVD, or any suitable deposition technique.

FIG. 14A illustrates an enlarged view of a portion of the semiconductor device structure 100 shown in FIG. 14, in accordance with some embodiments. Like the embodiment shown in FIG. 13A, the thickness T1 of the epitaxial bottom layer 148 may be about 10% to about 40% of the height H1 of the epitaxial bottom layer 148. The upper portion 148-1 of the epitaxial bottom layer 148, the etch stop layer 145, and the sacrificial layer 151 may have a combined lateral thickness T6 measuring at an elevation of the first semiconductor layer 106. Likewise, the thickness T2 of the upper portion 148-1 of the epitaxial bottom layer 148 may be about 5% to about 20% of the combined thickness T6. The etch stop layer 145 may have a thickness T4, and the thickness T4 may be about 5% to about 10% of the combined thickness T6. The sacrificial layer 151 may have a thickness T5, and the thickness T5 may be about 10% to about 20% of the combined thickness T6. The sacrificial layer 151 may have a height H3 measuring from a top surface 151t to a bottom surface 151b of the sacrificial layer 151. The bottom surface 151b is an interface defined by the sacrificial layer 151 and the etch stop layer 145. The height H3 of the sacrificial layer 151 may be about 50% to about 80% of the height H1 of the epitaxial bottom layer 148. In some embodiments, the thickness T5 is in a range of about 5 Angstroms to about 2 nm, which may vary depending on the space left in the recess 139 (FIG. 10).

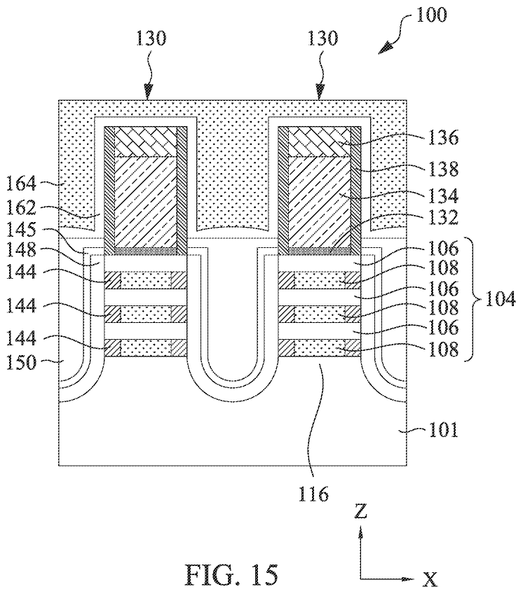

At block 1028, after formation of the sacrificial layer 150, a contact etch stop layer (CESL) 162 is conformally formed on the exposed surfaces of the semiconductor device structure 100, as shown in FIG. 15. The CESL 162 covers the exposed surfaces of the sacrificial layer 150 and the sacrificial gate structures 130. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, a first interlayer dielectric (ILD) layer 164 is formed on the CESL 162 over the semiconductor device structure 100. The materials for the first ILD layer 164 may include oxide formed with tetraethylorthosilicate (TEOS), un-doped silicate glass, or doped silicon oxide such as borophosphosilicate glass (BPSG), fused silica glass (FSG), phosphosilicate glass (PSG), boron doped silicon glass (BSG), and/or other suitable dielectric materials comprising Si, O, C, and/or H. The first ILD layer 164 may be deposited by a PECVD process or other suitable deposition technique. In some embodiments, after formation of the first ILD layer 164, the semiconductor device structure 100 may be subject to a thermal process to anneal the first ILD layer 164.

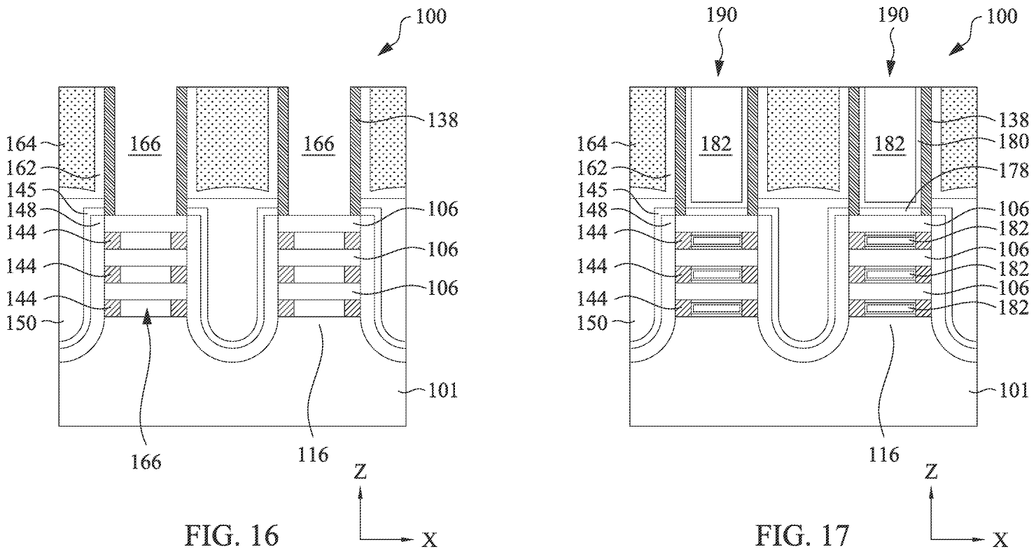

At block 1030, a planarization operation, such as CMP, is performed on the semiconductor device structure 100 to remove portions of the first ILD layer 164, the CESL 162, and the mask layer 136 until the sacrificial gate electrode layer 134 is exposed. Thereafter, the sacrificial gate structure 130, the cladding layer 117 (FIG. 8), and the second semiconductor layers 108 are removed, as shown in FIG. 16. The removal of the sacrificial gate structure 130 and the second semiconductor layers 108 forms an opening 166 between gate spacers 138 and between first semiconductor layers 106. The first ILD layer 164 protects the S/D cap layer 147 and the S/D epitaxial features 146 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the gate spacers 138, the first ILD layer 164, and the CESL 162.

After the removal of the sacrificial gate structure 130, the cladding layers 117 are exposed. The removal of the cladding layers 117 and the second semiconductor layers 108 exposes the dielectric spacers 144 and the first semiconductor layers 106. The removal process may be any suitable etch processes, such as dry etch, wet etch, or a combination thereof. The etch process may be a selective etch process that removes the cladding layers 117 and the second semiconductor layers 108 but not the gate spacers 138, the first ILD layer 164, the CESL 162, the dielectric spacers 144, and the first semiconductor layers 106. As a result, a portion of the first semiconductor layers 106 not covered by the dielectric spacers 144 is exposed in the opening 166.

At block 1032, replacement gate structures 190 are formed, as shown in FIG. 17. The replacement gate structures 190 each includes an interfacial layer (IL) 178, a gate dielectric layer 180, and a gate electrode layer 182. The interfacial layer (IL) 178 is formed to surround exposed surfaces of the first semiconductor layers 106 along the channel regions. The IL 178 may include or be made of an oxide (e.g., silicon oxide) formed by thermal or chemical oxidation of the first semiconductor layers 106, a nitride (e.g., silicon nitride, silicon oxynitride, oxynitride, etc.), and/or a dielectric layer (e.g., hafnium silicate). In one embodiment, the IL 178 is silicon oxide. The IL 178 may be formed by CVD, ALD, a clean process, or any suitable process. Next, the gate dielectric layer 180 is formed on the exposed surfaces of the semiconductor device structure 100 (e.g., on the IL 178, sidewalls of the gate spacers 138, the top surfaces of the first ILD layer 164, the CESL 162, and the dielectric spacers 144). The gate dielectric layer 180 may include or made of a high-k dielectric material, such as hafnium oxide (HfO₂), hafnium silicate (HfSiO), hafnium silicon oxynitride (HfSiON), hafnium aluminum oxide (HfAlO), hafnium lanthanum oxide (HfLaO), hafnium zirconium oxide (HfZrO), hafnium tantalum oxide (HfTaO), hafnium titanium oxide (HfTiO), lanthanum oxide (LaO), aluminum oxide (AlO), aluminum silicon oxide (AlSiO), zirconium oxide (ZrO), titanium oxide (TiO), tantalum oxide (Ta₂O₅), yttrium oxide (Y₂O₃), silicon oxynitride (SiON), or other suitable high-k materials. The gate dielectric layer 180 may be a conformal layer formed by a conformal process, such as an ALD process, a PECVD process, a molecular-beam deposition (MBD) process, or the like, or a combination thereof. The gate dielectric layer 180 may have a thickness in a range of about 0.3 nm to about 5 nm.

After formation of the IL 178 and the gate dielectric layer 180, the gate electrode layer 182 is formed on the gate dielectric layer 180. The gate electrode layer 182 fills the openings 166 (FIG. 16) and surrounds a portion of each of the first semiconductor layers 106. The gate electrode layer 182 includes one or more layers of conductive material, such as polysilicon, aluminum, copper, titanium, tantalum, tungsten, cobalt, molybdenum, tantalum nitride, nickel silicide, cobalt silicide, TIN, WN, WCN, TiAl, TiTaN, TiAlN, TaN, TaCN, TaC, TaSiN, metal alloys, other suitable materials, and/or combinations thereof. The gate electrode layers 182 may be formed by PVD, CVD, ALD, electro-plating, or other suitable method. In some embodiments, one or more optional conformal layers (not shown) can be conformally (and sequentially, if more than one) deposited between the gate dielectric layer 180 and the gate electrode layer 182. The one or more optional conformal layers can include one or more barrier and/or capping layers and one or more work-function tuning layers. The one or more barrier and/or capping layers may include or be a nitride, silicon nitride, carbon nitride, and/or aluminum nitride of tantalum and/or titanium; a nitride, carbon nitride, and/or carbide of tungsten; the like; or a combination thereof. The one or more work-function tuning layers may include or be a nitride, silicon nitride, carbon nitride, aluminum nitride, aluminum oxide, and/or aluminum carbide of titanium and/or tantalum; a nitride, carbon nitride, and/or carbide of tungsten; cobalt; platinum; the like; or a combination thereof.

Portions of the gate electrode layer 182, the one or more optional conformal layers (if any), and the gate dielectric layer 180 above the top surfaces of the first ILD layer 164, the CESL 162, and the gate spacers 138 may be removed by a planarization process, such as by a CMP process.

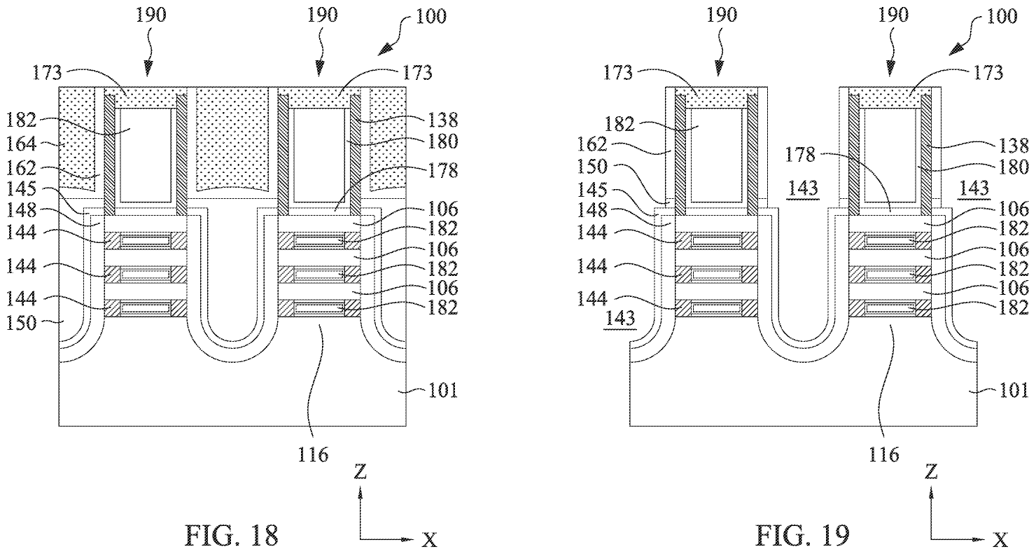

At block 1034, the gate electrode layer 182 may be subject to one or more metal gate etching back (MGEB) processes. The MGEB processes are performed so that the top surfaces of the gate electrode layer 182 and the gate dielectric layer 180 are recessed to a level below the top surface of the gate spacers 138. In some embodiments, the gate spacers 138 are also recessed to a level below the top surface of the first ILD layer 164, as shown in FIG. 18. A self-aligned contact layer 173 is formed over the gate electrode layer 182 and the gate dielectric layer 180 between the gate spacers 138. The self-aligned contact layer 173 may be a dielectric material having an etch selectivity relative to the first ILD layer 164. In some embodiments, the self-aligned contact layer 173 includes silicon nitride.

At block 1036, contact openings 143 are formed through the first ILD layer 164 and the CESL 162 to expose the sacrificial layer 150. Then, an etch process is performed to remove the sacrificial layer 150, as shown in FIG. 19. The contact openings 143 may be formed by a patterning process, which includes lithography processes and/or one or more etching processes, such as an anisotropic etching process. The one or more etching processes may be a plasma etching process employing etchants such as chlorine-containing gas, a bromine-containing gas, and/or a fluorine-containing gas. In some embodiments, the etch process is a multi-step etching process in which a first etch step can be an isotropic etch process that selectively removes the ILD 164 and the CESL 162 without substantially removing the replacement gate structures 190, and a second etch step can be an isotropic etch process that selectively removes the sacrificial layer 150 without substantially removing the replacement gate structures 190 and the etch stop layer 145. In some embodiments, the second etch step may continue until the etch stop layer 145 is fully exposed. In such cases, a portion of the etch stop layer 145 may be removed after the second etch step. However, the etch stop layer 145 protects the underlying epitaxial bottom layer 148 during removal of the sacrificial layer 150. In some embodiments, the isotropic etch process is performed such that the vertical portion of the CESL 162 is substantially intact after the etch process, leaving a small portion of the sacrificial layer 150 between the etch stop layer 145 and the CESL 162. The remaining sacrificial layer 150 may have a curved (e.g., concave) profile, as can be seen in FIG. 22A.

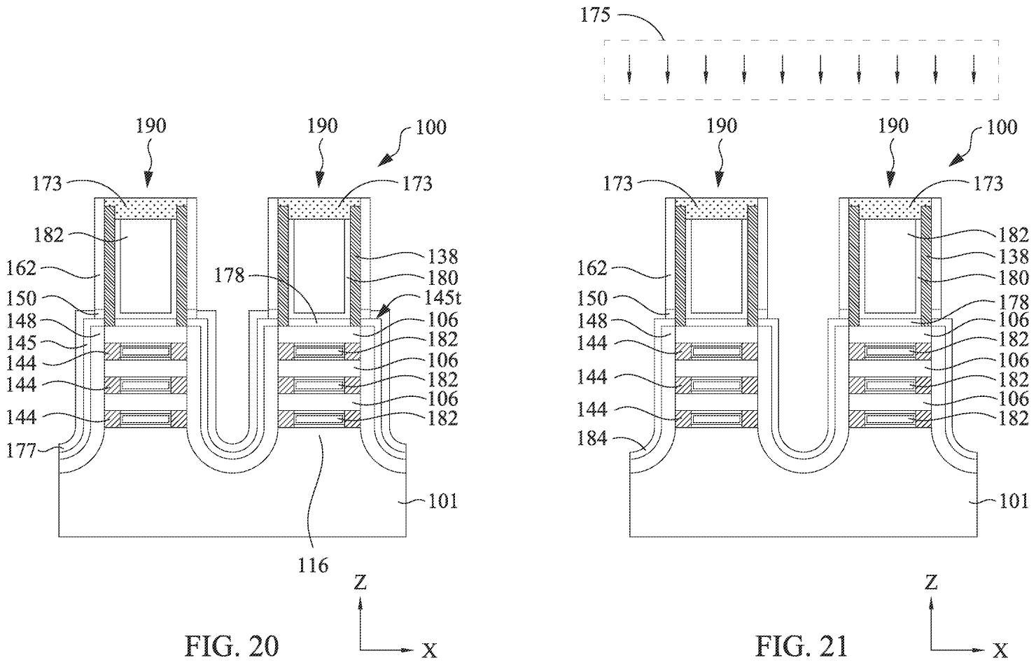

At block 1038, a fill contact layer 177 is formed on the exposed surfaces of the etch stop layer 145, as shown in FIG. 20. The fill contact layer 177 is to be reacted with the etch stop layer 145 and form a silicide layer 184 (FIG. 20). In some embodiments, a portion of the fill contact layer 177 is formed on the top surface 145t of the etch stop layer 145 and in contact with the sacrificial layer 150 disposed between the gate spacer 138 and the etch stop layer 145. The fill contact layer 177 may be formed from a metal, a noble metal, a refractory metal, a rare earth metal, alloys thereof, or combinations thereof. Exemplary material for the fill contact layer 177 may include, but is not limited to, W, Co, Ru, Ti, Ni, Cu, Au, Ag, Pt, Pd, Ir, Os, Rh, Al, Mo, TiN, TaN, or the like. The fill contact layer 177 is a conformal layer, and may be formed by a suitable deposition process, such as ALD, CVD, PVD, plating, or other conformal deposition technique.

At block 1040, the semiconductor device structure 100 is subjected to a thermal treatment 175. The thermal treatment causes the fill contact layer 177 to chemically react with silicon in the etch stop layer 145 and convert the fill contact layer 177 and a portion of the etch stop layer 145 into a silicide layer 184, as shown in FIG. 21. The silicide layer 184 generally follows the profile of the fill contact layer 177. In some embodiments, the silicide layer 184 may have a U-shaped profile extending in a direction across sidewall surfaces of the first semiconductor layers 106. Depending on the material of the fill contact layer 177 and the etch stop layer 145, the silicide layer 184 may be an alloy, composition, or mixture of the fill contact layer 177 and the etch stop layer 145. The thermal treatment 175 may be performed in-situ or ex-situ and can be any type of anneal, such as rapid thermal anneal, a spike anneal, a soak anneal, a laser anneal, etc. The thermal treatment 175 may be performed for about 1 second to about 3 minutes, and at a temperature range of about 500 degrees Celsius to about 850 degrees Celsius. The thermal treatment 175 may be performed in an atmosphere of gas, such as an oxygen-containing gas, a hydrogen-containing gas, an argon-containing gas, or a helium-containing gas, or any combinations thereof. Exemplary gas may include, but is not limited to, N₂, NH₃, O₂, N₂O, Ar, He, H₂, etc.

In some embodiments, the unreacted dopant atoms (e.g., boron) in the etch stop layer 145 may diffuse from the top portion of the etch stop layer 145 to the bottom portion of the etch stop layer 145 and accumulated at and/or near an interface of the etch stop layer 145 and the epitaxial bottom layer 148. After the thermal treatment 175, the dopant concentration (e.g., boron) at and/or near the interface of the silicide layer 184 and the epitaxial bottom layer 148 is greater than the dopant concentration (e.g., boron) at and/or near the interface of the silicide layer 184 and the subsequent S/D contact 186.

At block 1042, a conductive material is deposited over the silicide layer 184 to form S/D contacts 186, as shown in FIG. 22. The S/D contact 186 is conductively coupled to the epitaxial bottom layer 148, which is in contact with the channel layers (e.g., first semiconductor layers 106), through the silicide layer 184. The S/D contact 186 may be considered to have a first portion 186-1 extending between two adjacent replacement gate structures 190, and a second portion 186-2 extending between two adjacent channel regions (e.g., stacks of first semiconductor layers 106). The second portion 186-2 of the S/D contact 186 is being surrounded by the silicide layer 184 and the epitaxial bottom layer 148. Unlike the traditional S/D contact which is typically sitting on a bulk of S/D epitaxial feature, a portion of the S/D contact 186 is extended into the S/D feature and has at least three surfaces (e.g., a bottom 186b and two opposing sidewalls 186s of the S/D contact 186) being surrounded and in contact with the silicide layer 184.

The conductive material fills in the contact openings 143 (FIG. 19) and to a height over a top surface of the topmost first semiconductor layer 106. In some embodiments, the conductive material is deposited such that a top surface 186t is at an elevation that is about 35% or greater of the height of the contact opening 143, such as about 50% or greater of the height of the contact opening 143, for example about 60% to about 80% of the height of the contact opening 143. The S/D contacts 186 may include the same material as the fill contact layer 177. Likewise, the S/D contacts 186 may include, but is not limited to, W, Co, Ru, Ti, Ni, Cu, Au, Ag. Pt, Pd, Ir, Os, Rh, Al, Mo, TaN, or the like. In some embodiments, the S/D contacts 186 are formed of Co, W, Ru, or Mo. The S/D contacts 186 may be formed by a suitable deposition process, such as CVD, PVD, plating, ALD, or other suitable technique. Additionally or alternatively, the conductive material may overfill the contact openings 143 and over a top surface of the SAC layer 137, and a CMP process may be performed to remove excessive portion of the conductive material layer until the top surface of SAC layer 137 is exposed. Then, an etch process may be further performed to recess the S/D contacts 186 until the top surface 186t is at an elevation that is about 35% to about 80% of the height of the contact opening 143.

At block 1044, a second ILD layer 188 is formed on the S/D contacts 186, the CESL 162, and the SAC layer 137, as shown in FIG. 23. The second ILD layer 188 may be deposited until a height over the SAC layer 137 is reached. The second ILD layer 188 may include the same material as the first ILD layer 164, and may be deposited using the same fashion as the first ILD layer 164.

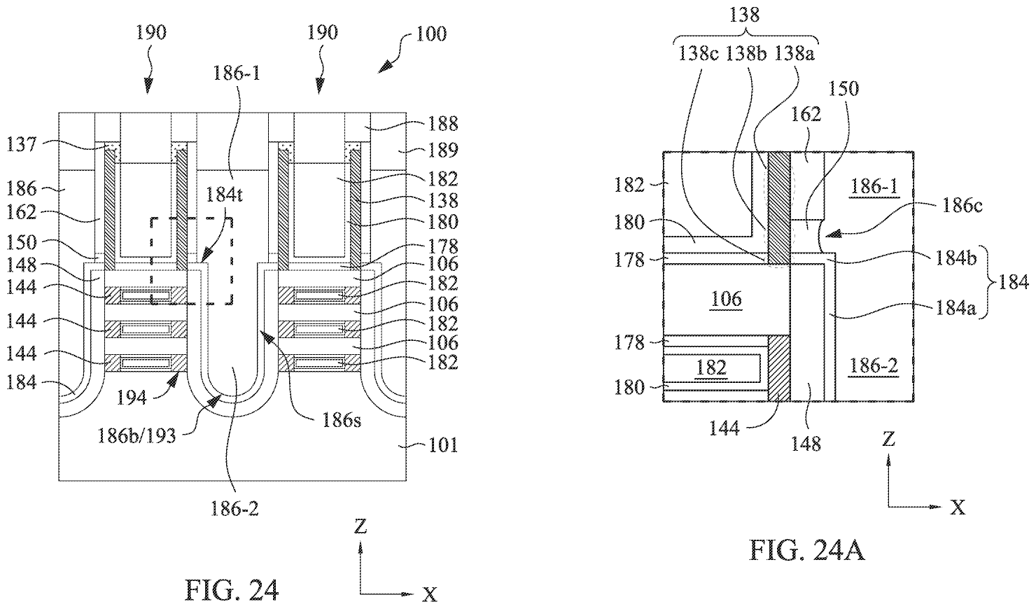

At block 1046, portions of the second ILD layer 188 and SAC layer 137 are removed to form contact via openings. The contact via openings are aligned so that some contact via openings extend through the second ILD layer 188 to expose a top surface of the S/D contacts 186, while other contact via openings extend through the second ILD layer 188 and the SAC layer 137 to expose the gate electrode layer 182, as shown in FIG. 24. The contact via openings may be formed using one or more etching processes, such as anisotropic etch processes. The etchants used during the one or more etching processes are chosen to selectively remove the dielectric materials (e.g., second ILD layer 188 and the SAC layer 137) without significantly affecting the metallic material (e.g., S/D contacts 186 and the gate electrode layers 182). Thereafter, the contact via openings are filled with a conductive material to form conductive features 189. The conductive features 189 in contact with the S/D contacts 186 may be referred to as S/D contact vias, and the conductive features 189 in contact with the gate electrode layer 182 may be referred to as metal gate contact via, respectively. The conductive material may be or include W, Co, Cu, Ru, Al, Au, Ag, alloys thereof, or a combination thereof, and may be deposited by CVD, ALD, PVD, or any suitable deposition technique. Portions of the conductive features 189 above the top surfaces of the second ILD layer 188 may be removed by a planarization process, such as by a CMP process. As a result of the planarization process, the top surfaces of the second ILD layer 188 and the conductive features 189 are substantially co-planar.

As such, the S/D contact 186 is extended a distance into almost the bottom of the contact opening 143 (FIG. 19). Since the silicide layer 184 follows the profile of the S/D contact 186, the bottom surface of the S/D contact 186 and the silicide layer 184 may define an interface 193, and the IL 178 (or the dielectric spacer 144) and the well portion 116 may define an interface 194. The interface 193 may be at a first elevation, and the interface 194 may be at a second elevation higher than the interface 193. A portion of the S/D contact 186 is formed on a top surface 184t of the silicide layer 184, resulting in the silicide layer 184 with a T-shaped or bar-shaped profile. Correspondingly, the silicide layer 184 and the epitaxial bottom layer 148 have a substantially U-shaped, respectively. The T-shaped or bar-shaped profile allows the contact surface area of the S/D contact 186 to be increased when compared to the traditional S/D contact that has its bottom landed on a bulk S/D epitaxial feature occupying the majority space of the contact opening 143. Particularly, the bottom surface of the traditional S/D contact may stop at an elevation around the height of the topmost first semiconductor layer 106. A larger surface contact area of the S/D contact 186 and the fact that the S/D contact 186 extending in a direction across all sidewall surfaces of the first semiconductor layers 106 together make the current conduction with the channel regions (i.e., first semiconductor layers 106) to be done evenly and efficiently. In addition, the S/D contact 186 with an increased surface contact area can boost device performance.

FIG. 24A illustrates an enlarged view of a portion of the semiconductor device structure 100, in accordance with some embodiments. As can be seen, the epitaxial bottom layer 148 is in contact with the first semiconductor layer 106, the dielectric spacer 144, and the silicide layer 184. The silicide layer 184 has a first portion 184a disposed between and in contact with the S/D contact 186 and the epitaxial bottom layer 148, and a second portion 184b disposed between and in contact with the epitaxial bottom layer 148 and the sacrificial layer 150. The gate spacer 138 has a first portion 138a disposed between and in contact with the IL 178 and the second portion 184b of the silicide layer 184, a second portion 138b disposed between and in contact with the gate dielectric layer 180 and the sacrificial layer 150, and a third portion 138c disposed between and in contact with the gate dielectric layer 180 and the CESL 162. In some embodiments, the S/D contact 186 has a portion 186c extending into the sacrificial layer 150. The portion 186c has a curved surface profile. Similarly, the sacrificial layer 150 has a curved surface corresponding to the profile of the portion 186c of the S/D contact 186.

It is understood that the semiconductor device structure 100 may undergo further complementary metal oxide semiconductor (CMOS) and/or back-end-of-line (BEOL) processes to form various features such as transistors, contacts/vias, interconnect metal layers, dielectric layers, passivation layers, etc. The semiconductor device structure 100 may also include backside contacts (not shown) on the backside of the substrate 101 so that either source or drain of the epitaxial S/D features is connected to a backside power rail (e.g., positive voltage VDD or negative voltage VSS) through the backside contacts.

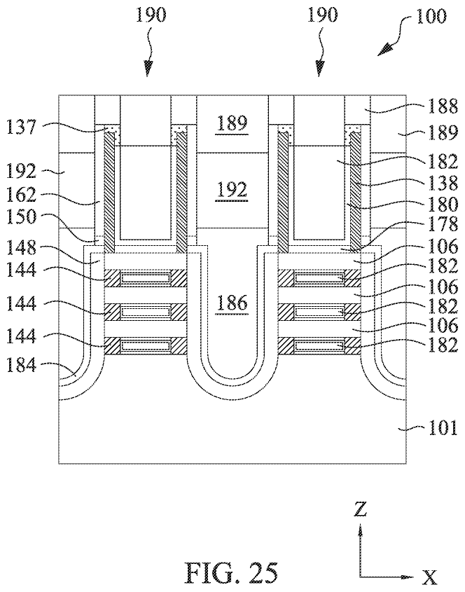

FIG. 25 illustrates a cross-sectional side view of a semiconductor device structure 200, in accordance with some alternative embodiments. The embodiment shown in FIG. 25 is substantially identical to the embodiment of FIG. 24 except that a contact metal layer 192 is further disposed between the S/D contact 186 and the conductive features 189. The contact metal layer 192 forms part of the S/D contact. In this embodiment, the S/D contact 186 may use a material that has good gap filling capability to ensure the contact openings are properly filled without voids. The contact metal layer 192 may use a material with a low contact resistance (Rcsd) to fill the remainder of the contact opening. Since a significant portion of the S/D contact is made of a low contact resistance contact metal layer 192, the overall contact resistance of the S/D contact can be reduced.

The S/D contact 186 may be deposited such that the top surface of the S/D contact 186 is at an elevation slightly above the top surface of the silicide layer 184. In some embodiments, the S/D contact 186 is deposited such that the top surface of the S/D contact 186 is at an elevation slightly above an interface defined by the sacrificial layer 150 and the CESL 162. In various embodiments, the S/D contact 186 may have a first contact resistance value and the contact metal layer 192 may have a second contact resistance value lower than the first contact resistance value. The contact metal layer 192 may include the same material as the fill contact layer 177, and may be deposited by PVD, CVD, ALD, electro-plating, or other suitable method. Exemplary material for the contact metal layer 192 may include, but is not limited to, W, Co, Ru, Ti, Ni, Cu, Au, Ag, Pt, Pd, Ir, Os, Rh, Al, Mo, TiN, TaN, or the like.

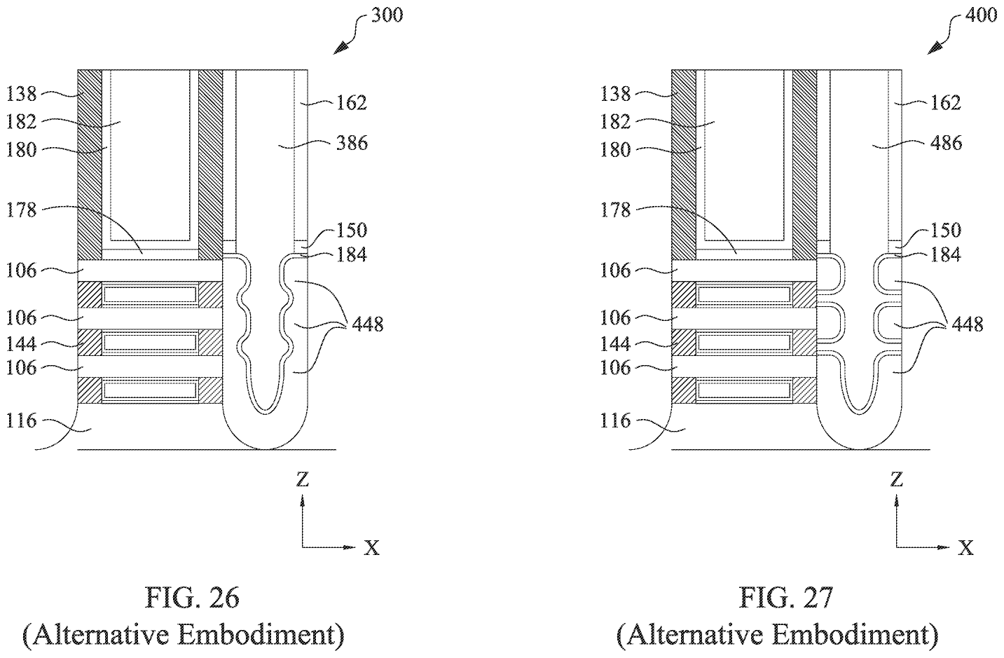

FIG. 26 illustrates a cross-sectional side view of a semiconductor device structure 300, in accordance with some alternative embodiments. This embodiment is similar to the embodiment shown in FIG. 24 except that an epitaxial bottom layer 348 has an inner surface formed with a wavy profile. The epitaxial bottom layer 348 may include the same material as the epitaxial bottom layer 148, and may be deposited using a conformal deposition technique, or any suitable deposition process in a similar fashion as discussed above with respect to FIG. 11. After the formation of the epitaxial bottom layer 348, an etch stop layer (e.g., etch stop layer 145) and a sacrificial layer (e.g., sacrificial layer 150) may be sequentially formed over the epitaxial bottom layer 348. The sacrificial layer is then removed and a thermal treatment is performed to convert the etch stop layer into the silicide layer 184. A S/D contact 386 (e.g., S/D contact 186) is then deposited on the silicide layer 184. The S/D contact 386 is in contact with the sacrificial layer 150, the CESL 162, and the silicide layer 184, which follows the wavy profile of the epitaxial bottom layer 348. In cases where the epitaxial bottom layer 348 includes boron-doped silicon (Si: B), the epitaxial bottom layer 348 may be formed by exposing the first semiconductor layers 106, the dielectric spacer 144, and the well portion 116 to silicon-containing precursor(s) and p-type dopant-containing precursor(s). Due to the semiconductor material (of the epitaxial bottom layer 348) being less attractive to the dielectric surface of the dielectric spacer 144 during the deposition, the epitaxial bottom layer 348 may have higher deposition rate at the first semiconductor layers 106 than that at the dielectric spacer 144. As a result, the epitaxial bottom layer 348 is formed on the exposed surfaces of the first semiconductor layers 106 and the dielectric spacer 144 with a wavy profile. This wavy profile allows the S/D contact 386 to form with increased contact surface area. As a result, the device performance is increased.

FIG. 27 illustrates a cross-sectional side view of a semiconductor device structure 400, in accordance with some alternative embodiments. This embodiment is similar to the embodiment shown in FIG. 26 except that an epitaxial bottom layer is formed primarily on the first semiconductor layers 106, resulting in a plurality of epitaxial bottom layer blocks 448. Portions of a S/D contact 486 are extending between the epitaxial bottom layer blocks 448 and in contact with the dielectric spacers 144. Likewise, portions of a silicide layer 384 (e.g., the silicide layer 184) are in contact with the dielectric spacers 144. During the deposition, the epitaxial bottom layer may grow both vertically and horizontally to form facets, which may correspond to crystal planes of the material of the first semiconductor layers 106 and exposed surfaces of the substrate 101 (e.g., well portion 116). Due to different growth rates on different surface planes, facets can be formed. For example, during the growth of the epitaxial bottom layer, the growth rate on (111) planes of the first semiconductor layer 106 may be lower than the growth rate on other planes, such as (110) and (100) planes of the substrate 101. Therefore, facets are formed as a result of difference in growth rates of the different planes. In one embodiment, each epitaxial bottom layer block 448 may have a rhombus-like shape. Comparing to the embodiment of FIG. 25 or 26, the facets of the epitaxial bottom layer block 448 allows the S/D contact 486 to form with an additional contact surface area. As a result, the device performance is further enhanced.

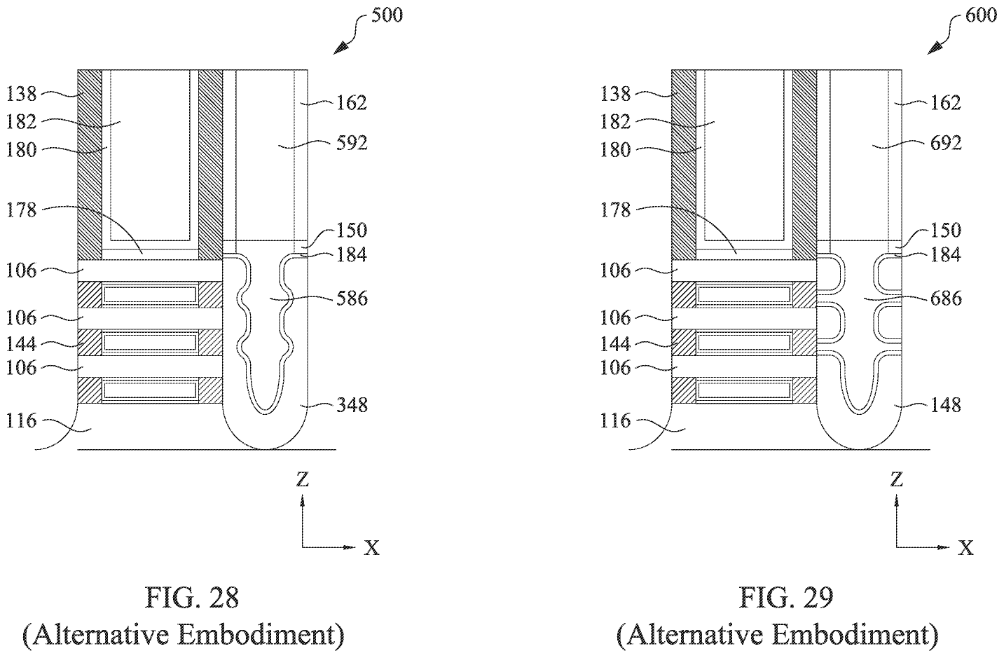

FIG. 28 illustrates a cross-sectional side view of a semiconductor device structure 500, in accordance with some alternative embodiments. This embodiment is similar to the embodiment shown in FIG. 26 except that the upper portion of a S/D contact 586 (e.g., the S/D contact 186) is being replaced with a contact metal layer 592, such as the contact metal layer 192 discussed above with respect to FIG. 25. This embodiment combines the benefits of increased contact surface area for the S/D contact 586 and lower contact resistance due to the inclusion of the contact metal layer 592.

FIG. 29 illustrates a cross-sectional side view of a semiconductor device structure 600, in accordance with some alternative embodiments. This embodiment is similar to the embodiment shown in FIG. 27 except that the upper portion of a S/D contact 486 is being replaced with a contact metal layer 692, such as the contact metal layer 192 discussed above with respect to FIG. 25. Likewise, this embodiment combines the benefits of increased contact surface area for a S/D contact 686 (e.g., the S/D contact 186) and lower contact resistance due to the inclusion of the contact metal layer 692.

Various embodiments of the present disclosure relate to a nanosheet device structure having a bar-shaped like S/D contact extended vertically between two adjacent channel regions. The improved S/D contact is formed by first forming a conformal epitaxial bottom layer on exposed surfaces of a recess for the S/D features, forming a conformal etch stop layer using high Ge concentration on the epitaxial bottom layer, followed by a sacrificial layer to fill in the remainder of the recess. After the replacement gate process, the sacrificial layer is then removed, and the etch stop layer is thermally treated to form a silicide layer. The S/D contact is then formed on the silicide layer. Since the resulting S/D contact is formed with a low contact resistance and an increased surface contact area, the device performance is improved.

An embodiment is a semiconductor device structure. The semiconductor device structure includes a source/drain (S/D) feature disposed in a recess between two adjacent channel regions, wherein the S/D feature comprises an epitaxial layer conformally deposited on an exposed surface of the recess. The structure also includes a silicide layer conformally disposed on the S/D feature, and a S/D contact disposed on the silicide layer, wherein the S/D contact has a first portion extending into the recess, and the first portion has at least three surfaces being surrounded by the silicide layer and the S/D feature.

Another embodiment is a semiconductor device structure. The semiconductor device structure includes a plurality of semiconductor layers stacked vertically over a substrate, a gate electrode layer surrounding a portion of each semiconductor layer, a gate dielectric layer disposed between the gate electrode layer and each semiconductor layer, a source/drain (S/D) epitaxial layer in contact with each of the plurality of semiconductor layers, and a S/D contact extending in a direction across a sidewall surface of each of the plurality of semiconductor layers, and a bottom of the S/D contact is at an elevation below an interface defined by the substrate and the gate dielectric layer.

A further embodiment is a method for forming a semiconductor device structure. The method includes depositing a sacrificial gate structure over a portion of a first fin structure and a second fin structures formed from a substrate, wherein each first and second fin structure comprises a plurality of first semiconductor layers and a plurality of second semiconductor layers alternatingly stacked. The method also includes removing portions of the first and second fin structures not covered by the sacrificial gate structure to form a recess on opposite sides of the sacrificial gate structure. The method also includes forming a source/drain (S/D) epitaxial layer on exposed surfaces of the recess, wherein the S/D epitaxial layer is in contact with each first semiconductor layer, and the S/D epitaxial layer has a first germanium concentration. The method also includes forming an etch stop layer on the S/D epitaxial layer, wherein the etch stop layer has a second germanium concentration lower than the first germanium concentration. The method also includes filling the trench with a sacrificial layer, removing the plurality of second semiconductor layers to expose portions of first semiconductor layers of the first and second fin structures, forming a gate electrode layer to surround at least the exposed portion of one of the plurality of first semiconductor layers of the first and second fin structures. The method also includes removing the sacrificial layer to expose the etch stop layer, converting the etch stop layer to a silicide layer, and forming a source/drain (S/D) contact on the silicide layer, wherein the S/D contact has a first portion extending into the recess, and the first portion has at least three surfaces being surrounded by the silicide layer and the S/D feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a source/drain (S/D) feature disposed in a recess between two adjacent channel regions, wherein the S/D feature comprises an epitaxial layer conformally deposited on an exposed surface of the recess;
a silicide layer conformally disposed on the S/D feature; and
a S/D contact disposed on the silicide layer, wherein the S/D contact has a first portion extending into the recess, and the first portion has at least three surfaces being surrounded by the silicide layer and the S/D feature.

2. The semiconductor device structure of claim 1, wherein the S/D contact further comprises:
a second portion disposed over the first portion, wherein the second portion is extended between two adjacent gate structures.

3. The semiconductor device structure of claim 2, wherein the epitaxial layer has a top surface at an elevation that is equal to or greater than a top surface of at least one channel region.

4. The semiconductor device structure of claim 1, wherein the S/D feature has a general U-shaped profile.

5. The semiconductor device structure of claim 1, wherein the silicide layer has a general U-shaped profile.

6. The semiconductor device structure of claim 1, wherein the epitaxial layer has n-type or p-type dopants distributed constantly or gradually along a thickness of the epitaxial bottom layer.

7. The semiconductor device structure of claim 1, wherein the epitaxial layer is a semiconductor layer having an atomic percentage of germanium in a range of about 40 at. % to about 60 at. %.

8. A semiconductor device structure, comprising:
a plurality of semiconductor layers stacked vertically over a substrate;
a gate electrode layer surrounding a portion of each semiconductor layer;
a gate dielectric layer disposed between the gate electrode layer and each semiconductor layer;
a source/drain (S/D) epitaxial layer in contact with each of the plurality of semiconductor layers; and
a S/D contact extending in a direction across a sidewall surface of each of the plurality of semiconductor layers, and a bottom of the S/D contact is at an elevation below an interface defined by the substrate and the gate dielectric layer.

9. The semiconductor device structure of claim 8, further comprising:
a silicide layer disposed between and in contact with the S/D contact and the S/D epitaxial layer.

10. The semiconductor device structure of claim 9, further comprising:
a contact etch stop layer (CESL) disposed over the S/D epitaxial layer; wherein a portion of the silicide layer is disposed between the S/D epitaxial layer and the CESL.

11. The semiconductor device structure of claim 10, further comprising:
a sacrificial layer disposed between and in contact with the CESL and the silicide layer.

12. The semiconductor device structure of claim 11, wherein the sacrificial layer has a curved surface, and a portion of the S/D contact is extended into and in contact with the curved surface of the sacrificial layer.

13. The semiconductor device structure of claim 8, wherein the S/D epitaxial layer has a general U-shaped profile.

14. The semiconductor device structure of claim 13, wherein the S/D contact has a general T-shaped profile.

15. The semiconductor device structure of claim 8, wherein the S/D epitaxial layer has an outer surface in contact with each of the plurality of semiconductor layers and an inner surface formed with a wavy profile.

16. The semiconductor device structure of claim 8, further comprising:
a dielectric spacer disposed between two adjacent semiconductor layers and in contact with the gate dielectric layer and a portion of the S/D contact.

17. A method for forming a semiconductor device structure, comprising:
depositing a sacrificial gate structure over a portion of a first fin structure and a second fin structures formed from a substrate, wherein each first and second fin structure comprises a plurality of first semiconductor layers and a plurality of second semiconductor layers alternatingly stacked;
removing portions of the first and second fin structures not covered by the sacrificial gate structure to form a recess on opposite sides of the sacrificial gate structure;
forming a source/drain (S/D) epitaxial layer on exposed surfaces of the recess, wherein the S/D epitaxial layer is in contact with each first semiconductor layer, and the S/D epitaxial layer has a first germanium concentration;
forming an etch stop layer on the S/D epitaxial layer, wherein the etch stop layer has a second germanium concentration lower than the first germanium concentration;
filling the trench with a sacrificial layer;
removing the plurality of second semiconductor layers to expose portions of first semiconductor layers of the first and second fin structures;
forming a gate electrode layer to surround at least the exposed portion of one of the plurality of first semiconductor layers of the first and second fin structures;
removing the sacrificial layer to expose the etch stop layer;
converting the etch stop layer to a silicide layer; and
forming a source/drain (S/D) contact on the silicide layer, wherein the S/D contact has a first portion extending into the recess, and the first portion has at least three surfaces being surrounded by the silicide layer and the S/D feature.

18. The method of claim 17, wherein the sacrificial layer has a third germanium concentration greater than the first germanium concentration.

19. The method of claim 17, wherein the sacrificial layer is a doped semiconductor layer.

20. The method of claim 17, further comprising:
after removing the sacrificial layer, forming a fill contact layer on the etch stop layer, wherein the fill contact layer comprises the same material as the S/D contact.
